(19) United States
(12) Patent Application Publication
(10) Pub. No.: US 2008/0105879 A1
(43) Pub. Date: May 8, 2008

(54) PROCESS AND SYSTEM FOR LASER ANNEALING AND LASER-ANNEALED SEMICONDUCTOR FILM

(75) Inventors: Teruhiko Kuramachi, Ashigarakami-gun (JP); Hiroshi Sunagawa, Ashigarakami-gun (JP); Hiroyuki Hiiro, Ashigarakami-gun (JP); Atsushi Tanaka, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/865,117

(22) Filed: Oct. 1, 2007

(30) Foreign Application Priority Data
Sep. 29, 2006 (JP) 2006-269029

(51) Int. Cl. H01L 29/04; H01L 21/268; G21K 5/00

(52) U.S. Cl. 257/75; 438/795; 250/492.2; 257/E21.347; 257/E29.003

(57) ABSTRACT

In a laser annealing process for transforming a noncrystalline semiconductor film into a laterally-crystallized film: irradiation of a region with laser light and a shift of the position of the region to be irradiated are repeated, where the shift is made so that each region to be irradiated contains a subregion of granular crystals produced by previous irradiation and a subregion of noncrystalline semiconductor material which has not yet been crystallized, and the shifted region is irradiated under such a condition that the granular crystals and the noncrystalline semiconductor material which are contained in the second region are transformed into lateral crystals without melting one or more regions of lateral crystals produced in the semiconductor film by previous irradiation.

### BACKGROUND OF THE INVENTION

1. Field of the Invention

The present invention relates to a laser annealing process and a laser annealing system which perform laser annealing of a noncrystalline semiconductor film. In addition, the present invention relates to a semiconductor film produced by the above laser annealing process. Further, the present invention relates to a semiconductor device such as a thin-film transistor (TFT), and to an electro-optic device using the semiconductor device.

2. Description of the Related Art

Currently, the active-matrix type driving systems are widely used in the electro-optic devices such as the electroluminescence (EL) devices and the liquid crystal (display) devices. In the active-matrix type driving systems, a great number of pixel electrodes arrayed in a matrix are driven through the thin-film transistors (TFTs) arranged in correspondence with the pixel electrodes. Specifically, in some active-matrix type driving systems, a pixel part and a driver part are formed on a substrate. The pixel part is realized by the pixel electrodes and the great number of TFTs for pixel switching arrayed in a matrix, and the driver part has a driver circuit constituted by a plurality of TFTs and drives the pixel part.

In the active layers of the TFTs, noncrystalline or polycrystalline silicon films are widely used. From the viewpoint of the element characteristics such as carrier mobility, it is desirable that the silicon films realizing the active layers (in particular, the active layers in the TFTs for use in a driver circuit) have high crystallinity.

In the manufacture of the polysilicon TFTs, for example, a noncrystalline (amorphous) silicon (a—Si) film is first formed, and is then transformed into a polycrystal by laser annealing, which is realized by irradiating the noncrystalline silicon with laser light. Currently, the excimer laser is widely used as the laser light in the laser annealing, and the laser annealing using the excimer laser is called the ELA (excimer laser annealing). The excimer laser is pulse-oscillated laser in the ultraviolet wavelength range having wavelengths of 308 nm or shorter, and the polycrystals produced by the ELA technique are granular crystals having small grain size. The reason for the production of such granular crystals is considered as indicated in the paragraphs Nos. 0005 and 0036 in Japanese Unexamined Patent Publication No. 2005-072183 (hereinafter referred to as JPP 2005-072183) and the paragraphs Nos. 0007 and 0059 in the corresponding U.S. Patent Application Publication No. 20060051943 (herein after referred to as US 20060051943). That is, the absorptance of the excimer laser light in the silicon film is great regardless of the crystalline quality, so that the excimer laser light is greatly absorbed at the surface of the silicon film, and a great temperature gradient is produced in the thickness direction. Thus, crystals grow along the thickness direction, and hardly grow in the lateral directions.

As indicated in the paragraph No. 0006 in JPP 2005-072183 and the paragraph No. 0004 in US 20060051943, it is possible to grow lateral crystals having large grain size in the relative scanning direction by relatively scanning a noncrystalline silicon film with continuous-wave laser light having a wavelength of 350 nm or longer.

In the case where a laser head emitting continuous-wave laser light having a wavelength of 350 nm or longer is used, in order to supply annealing energy enabling growth of lateral crystals, the maximum width of the beam spot is limited to approximately 10 mm. Assume that the surface of the substrate is parallel to the x-y plane, the main (relative) scanning direction of the laser light is parallel to the x direction, and the sub (relative) scanning direction of the laser light is parallel to the y direction. In order to anneal the entire noncrystalline silicon film, it is necessary to repeat a relative scan of the noncrystalline silicon film with the laser light along a line in the x direction. That is, it is necessary to shift the irradiated position in the y direction every time a relative scan of the noncrystalline silicon film with the laser light along a line in the x direction is completed, and then the next relative scan along a line in the x direction is performed at the shifted y position. Normally, the operation of shifting the laser light is performed so that the region irradiated by each relative scan along a line in the x direction partially overlaps the region irradiated by an immediately preceding relative scan along a line in the x direction.

When each relative scan of the noncrystalline silicon film with the laser light along a line in the x direction is performed at a y position, granular crystals having small grain size (as illustrated as “Granular Poly-Si” in FIGS. 1A and 1B) are produced outside a region in which the lateral crystals are produced. This is because spreading of heat to regions around the region directly irradiated with the laser light cannot be prevented by control of the beam profile of the laser light, so that near-edge portions of the directly irradiated region and/or regions which are not directly irradiated with the laser light and to which heat spreads (i.e., regions which are located immediately outside the irradiated region) are not heated to the temperature which allows growth of lateral crystals, but are heated to the temperature which produces the granular crystals. Therefore, the granular crystals (granular poly-Si) are produced in the near-edge portions of the directly irradiated region and/or in the regions which are not directly irradiated with the laser light and to which heat spreads (i.e., the regions which are located immediately outside the irradiated region).

It is possible to consider that when the region irradiated by each relative scan along a line in the x direction partially overlaps the region irradiated by an immediately preceding relative scan along a line in the x direction, the granular crystals produced by the immediately preceding relative scan can be transformed into lateral crystals. However, the absorptance of the laser light having the wavelength of 350 nm or longer in the noncrystalline silicon (a—Si) is different from that in regions of granular crystals (granular poly-Si). Therefore, there is a possibility that the regions of granular crystals are not heated to the temperature necessary for transformation into lateral crystals when the regions of granular crystals are irradiated under the same irradiation condition as the noncrystalline silicon. In addition, when lateral crystals grow from granular crystals which behave as seed crystals, the lateral crystals can grow in undesirable directions, so that the directions of the growth of the lateral crystals can become ununiform.

Further, even when the granular crystals can be transformed into lateral crystals oriented in desirable directions, granular crystals having small grain size are still produced outside the region in which the lateral crystals are produced, so that it is impossible to eliminate the granular crystals. In addition, when already produced lateral crystals are irradiated with laser light, the lateral crystals are remelted, so that the crystallinity of the remelted lateral crystals can vary. Since the regions of the granular crystals contain a great number of grain boundaries, such regions have poor current characteristics. Therefore, when the TFTs are formed, it is necessary to avoid the regions of the granular crystals. For example, it may be necessary to contrive to relatively scan the laser light on the basis of the design information on the TFT formation positions so that the edges of the laser beam do not overlap the regions in which the TFTs are to be formed, or to selectively apply the laser light to only the regions of the noncrystalline semiconductor film in which the TFTs are to be formed.

Japanese Unexamined Patent Publication No. 2005-217209 (hereinafter referred to as JPP 2005-217209) and the corresponding U.S. Patent Application Publication No. 20050169330 A1 (hereinafter referred to as US 20050169330) disclose a technique for growing lateral crystals by use of the second harmonic generated by the Nd:YAG laser (having the wavelength of 532 nm) or the Nd:YVO₄ laser (having the wavelength of 532 nm), and a preferable condition for growing the lateral crystals. The preferable condition (indicated, for example, in the claims 4 and 8 and the paragraph No. 0037 in JPP 2005-217209 and the claims 4 and 9 and the paragraph No. 0052 in US 20050169330) includes the beam diameter of the laser light of 2 to 10 micrometers in a scanning direction, the relative scanning speed of 300 to 1000 mm/sec, and the output power density of 0.4 to 2.4 MW/cM² for the laser light having the beam diameter of 3 micrometers. In addition, JPP 2005-217209 (for example, in FIG. 8) and US 20050169330 (for example, in FIGS. 8A and 8B) also disclose selective application of the laser light to the regions in which the TFTs are to be formed.

JPP 2005-072183 (for example, in the claims 1 and 3, the paragraphs Nos. 0011 and 0045, and FIG. 7) and US 20060051943 (for example, in the claims 1 and 3, paragraphs Nos. 0034 and 0068, and FIG. 7) disclose a laser annealing technique in which a noncrystalline silicon film is concurrently and relatively scanned and irradiated with pulsed visible laser light having the wavelength of 350 nm or longer (such as the second harmonic of the Nd:YAG laser having the wavelength of 532 nm) and pulsed ultraviolet laser light having the wavelength shorter than 350 nm (such as a harmonic of higher order than the second harmonic of the Nd:YAG laser) so that the region irradiated with the pulsed visible laser light partially overlaps the region irradiated with the pulsed ultraviolet laser light.

Further, JPP 2005-072183 (for example, in the paragraph No. 0066 and FIG. 20) and US 20060051943 (for example, in the paragraph No. 0089 and FIG. 20) state that according to the above technique, the granular crystals (produced outside the region in which the lateral crystals are produced by the irradiation with the pulsed visible laser light) can be uncrystallized by the irradiation with the pulsed ultraviolet laser light, and noncrystalline regions produced by the irradiation with the pulsed ultraviolet laser light in each relative scan can be transformed into lateral crystals by reirradiation with the pulsed visible laser light in the next relative scan of the pulsed visible laser light along a shifted line, so that it is possible to obtain a silicon film having high crystallinity in the entire area.

Japanese Unexamined Patent Publication No. 2004-152978 (hereinafter referred to as JPP 2004-152978) indicates (for example, in the paragraph No. 0020) that since the absorptance of the second harmonic of the Nd:YLF laser (having the wavelength of 524 or 527 nm) in the noncrystalline silicon film is higher than that in the crystalline silicon by one or more orders of magnitude, the laser light having such a wavelength is more preferentially absorbed in the noncrystalline silicon than in the crystalline silicon, and the noncrystalline silicon can be preferentially melted and crystallized, so that it is possible to obtain a silicon film having high crystallinity.

Japanese Unexamined Patent Publication No. 2005-259809 (hereinafter referred to as JPP 2005-259809) indicates as follows. Since the absorptance of the laser light in the wavelength range of 390 to 640 nm (such as the second harmonic of the Nd:YAG laser having the wavelength of 532 nm) in the polycrystalline silicon is lower than in the noncrystalline silicon, even when polycrystalline silicon produced by irradiation of a noncrystalline silicon film with the laser light in the wavelength range of 390 to 640 nm is reirradiated with the same laser light, the polycrystalline silicon does not melt, and the characteristics of the polycrystalline silicon do not greatly vary (as indicated, for example, in the paragraph No. 0010 in JPP 2005-259809). However, since the absorptance of the laser light in the regions of granular crystals (as the polycrystalline silicon) having small grain size is low, it is impossible to increase the crystallinity of the regions of granular crystals, so that the reirradiated regions can be subtly visible to the naked eye (as indicated, for example, in the paragraph No. 0042 in JPP 2005-259809).

Therefore, JPP 2005-259809 proposes to use one of the following techniques (1) to (3) for laser annealing using the laser light in the wavelength range of 390 to 640 nm.

(1) JPP 2005-259809 proposes (for example, in the paragraph No. 0043) to set the irradiation energy in the lowest possible range in which sufficient carrier mobility for realizing TFTs can be achieved. Specifically, as indicated in the claim 1 in JPP 2005-259809, JPP 2005-259809 proposes that the laser output power E satisfy the condition,
Elow≦E<(Ehigh+Elow)/2,
where Elow and Ehigh are lower and upper limit values of the laser output power which realizes 80% or higher of the maximum carrier mobility, and determined on the basis of the relationship between the carrier mobility and the laser output power.

JPP 2005-259809 indicates (for example, in the paragraph No. 0048) that when the laser output power E is lowered from the upper limit value within the range of the laser output power which realizes the sufficient carrier mobility for realizing TFTs, it is possible to reduce the grain size of the polycrystalline silicon (granular crystals) produced at the near-edge portions of the region irradiated by a first relative scan, and easily remelt the granular crystals by a second relatively scan so as to improve the crystallinity.

(2) JPP 2005-259809 proposes (for example, in the claim 3 and the paragraph No. 0043) that the lengths L of the intensity-varying regions at the edges of the irradiated region be short, and preferably 3 mm or smaller. JPP 2005-259809 indicates (for example, in the paragraph No. 0050) that when the lengths L of the intensity-varying regions are set as above, it is possible to reduce a portion of the intensity-varying region which is transformed into polycrystalline silicon by the first relative scan (i.e., the region in which the granular crystals are produced by the first relative scan), and make deterioration of the reirradiated regions inconspicuous.

(3) JPP 2005-259809 proposes (for example, in the claim 5 and the paragraph No. 0043) to make the optical intensity in the second relative scan of the intensity-varying region higher than the optical intensity in the first relative scan. JPP 2005-259809 indicates (for example, in the paragraph No. 0052) that since the near-edge portion of the region irradiated by the first relative scan is reirradiated in the second relative scan with the laser light having higher intensity than the laser light in the first relative scan, the granular crystals can be easily remelted, so that the crystallinity can be improved.

In addition, JPP 2005-259809 (for example, in the claims 9 and 10, the paragraphs Nos. 0054 and 0056, and FIGS. 15 and 17) discloses a technique in which reflection films are formed in predetermined areas on a stage on which a substrate is to be placed, so that the laser light is reflected from the stage to the reirradiated region, and the near-edge portions of the region irradiated by the first relative scan is reirradiated in the second relative scan with the laser light having higher optical intensity.

Japanese Unexamined Patent Publication No. 2004-297055 (hereinafter referred to as JPP 2004-297055) discloses (for example, in the claim 1) a technique in which noncrystalline silicon is concurrently and overlappingly irradiated with first laser light having a wavelength at which the noncrystalline silicon exhibits an absorption coefficient of 5×10³/cm or greater and second laser light having a wavelength at which the noncrystalline silicon exhibits an absorption coefficient of 5×10²/cm or smaller and melted noncrystalline silicon exhibits an absorption coefficient of 5×10³/cm or greater. JPP 2004-297055 indicates (for example, in the paragraphs Nos. 0044 and 0084) an example in which a harmonic of a solid-state laser such as a YAG laser is used as the first laser light, and a fundamental of the solid-state laser is used as the second laser light. Further, JPP 2004-297055 indicates (for example, in the paragraphs Nos. 0015, 0016, and 0084 and FIG. 1(b)) that when noncrystalline silicon is irradiated as above, the second laser light is not absorbed in the normal silicon and is greatly absorbed in the noncrystalline silicon melted by the irradiation with the first laser light, so that it is possible to flatten the beam profile, reduce the regions in which granular crystals are produced, and enlarge the region of lateral crystals.

The techniques disclosed in the JPP 2005-072183 (US 20060051943), JPP 2004-152978, JPP 2005-259809, and JPP 2004-297055 utilize the difference in the absorption characteristics between the noncrystalline silicon and the polycrystalline silicon.

For example, the micrographs in FIG. 5 (a) and (b) in JPP 2004-297055 indicate that when the laser annealing technique disclosed in JPP 2004-297055 is used, the region of lateral crystals can be enlarged. However, the micrographs in FIG. 5 (a) and (b) in JPP 2004-297055 also indicate that granular crystals having small grain size are still produced outside the region of lateral crystals.

The paragraph No. 0009 in JPP 2005-072183 (the paragraph No. 0011 in US 20060051943) states that the noncrystalline silicon film can be substantially entirely transformed into lateral crystals. However, the present inventors consider that although the technique indicated by FIGS. 8, 13, and 14 and some other portions of JPP 2005-072183 can achieve the transformation into lateral crystals in the main scanning direction, regions of granular crystals or noncrystalline regions necessarily remain along the sub scanning direction.

According to the technique disclosed in JPP 2005-072183, rectangular pulsed laser beams are discontinuously applied to the noncrystalline silicon film so that the adjacent pulsed laser beams overlap. Therefore, it is considered that regions of nonlateral crystals (regions of granular crystals or noncrystalline regions) are produced along the periphery of the rectangular pulsed laser beams, i.e., along both the main and sub scanning directions. Such regions of nonlateral crystals cannot be entirely reannealed even when the next relative scan with the pulsed laser light is performed along a shifted line, so that regions of granular crystals or noncrystalline regions necessarily remain along the sub scanning direction.

Further, according to the technique disclosed in JPP 2005-072183, the regions of granular crystals are transformed into an amorphous state. Therefore, high irradiation energy is required for the transformation as indicated in FIG. 13 in JPP 2005-072183. However, it is considered that irradiation with such high irradiation energy causes troubles such as remelting of the lateral crystals and production of granular crystals.

As indicated above, according to the conventional techniques, even if transformation into lateral crystals can be achieved so that regions of lateral crystals extend in the main scanning direction, it is impossible to prevent granular crystals remaining along the boundaries between the regions of lateral crystals, so that the regions of lateral crystals cannot extend in the sub scanning direction beyond the width of the region irradiated by each relative scan. In addition, even if such granular crystals can be eliminated, it is impossible to eliminate discontinuity at the boundaries between the regions of lateral crystals.

### SUMMARY OF THE INVENTION

The present invention has been developed in view of the above circumstances.

The first object of the present invention is to provide a laser annealing process and a laser annealing system which can highly crystallize a noncrystalline semiconductor film in substantially the entire area, and transform the noncrystalline semiconductor film into a seamless laterally-crystallized film containing almost no granular crystals in the entire area of the film.

In addition, the second object of the present invention is to provide a semiconductor film which is produced by use of the above laser annealing process or laser annealing system, has high crystallinity, and is suitable for use as active layers in TFTs and the like.

Further, the third object of the present invention is to provide a semiconductor device and an electro-optic device using the above semiconductor film.

In order to accomplish the above first object, the first aspect of the present invention is provided. According to the first aspect of the present invention, there is provided a laser annealing process for performing laser annealing of a semiconductor film made of a noncrystalline semiconductor material. The laser annealing process comprises the steps of: (a) performing laser annealing of a first region of the semiconductor film by irradiating the first region with laser light under a condition for growing lateral crystals in the first region; and (b) performing laser annealing of a second region of the semiconductor film by irradiating the second region with the laser light under such a condition that granular crystals and the noncrystalline semiconductor material in the second region are transformed into lateral crystals without melting lateral crystals produced in the semiconductor film by previous irradiation with the laser light, where the second region is shifted from a region of the semiconductor film which has been already irradiated with the laser light and includes at least a part of granular crystals which are produced by previous irradiation with the laser light and at least a part of the noncrystalline semiconductor material in the semiconductor film which has not yet been crystallized.

In the laser annealing process according to the first aspect of the present invention, the step (b) can be repeated one or more times.

Further, in order to accomplish the aforementioned first object, the second aspect of the present invention is also provided. According to the second aspect of the present invention, there is provided a laser annealing system for performing laser annealing of a semiconductor film made of a noncrystalline semiconductor material. The laser annealing system comprises a laser head in which one or more laser-light sources are installed, and which irradiates the semiconductor film with the laser light so as to performs the steps (a) and (b) in the laser annealing process according to the first aspect of the present invention.

The granular crystals can be produced in the near-end portions of each region which is directly irradiated with the laser light, or in the regions which are not directly irradiated with the laser light and to which heat spreads (i.e., the regions which are located immediately outside the irradiated region), or in both the regions.

In this specification, the laser annealing includes both of the laser annealing of a region which is directly irradiated with the laser light and the laser annealing of a region which is not directly irradiated with the laser light and the crystalline state of which varies due to the spreading of heat.

Preferably, the laser annealing process according to the first aspect of the present invention and the laser annealing system according to the second aspect of the present invention may also have one or any possible combination of the following additional features (i) to (vii).

(i) The step (b) is executed so that the second region partially overlaps the third region of the semiconductor film which has been previously irradiated with the laser light.

(ii) In the case wherein the semiconductor film is a silicon film, the granular crystals in the second region, the noncrystalline semiconductor material in the second region, and lateral crystals produced in the semiconductor film respectively have absorptances A_{G}, A_{N}, and A_{L}, and the second region is irradiated in step (b) so that the absorptances A_{G}, A_{N}, and A_{L} satisfy the conditions,
0.82≦(A_{G}/A_{N})≦1.0, and (1)
(A_{L}/A_{N})≦0.70. (2)

In this specification, the expression “silicon film” means a film the main component of which is silicon, and the “main component” means a component the composition of which is 50% by weight. It is preferable that the silicon composition of the silicon films for use in TFTs be 90% or more by weight.

(iii) In the laser annealing process or system having the feature (ii), the laser light L has a wavelength λ, the semiconductor film has a thickness t, and the wavelength λ and the thickness t satisfy the condition,
0.8t+320 nm≦λ≦0.8t+400 nm. (3)

When the condition (3) is satisfied, it is possible to satisfy the aforementioned conditions (1) and (2).

(iv) The laser light is emitted from one or more semiconductor lasers having an oscillation wavelength in a range of 350 to 500 nm.

(v) In the laser annealing process or system having the feature (iv), the one or more semiconductor lasers are GaN-based semiconductor lasers or ZnO-based semiconductor lasers.

(vi) The laser head concurrently irradiates part of each of the first and second regions with the laser light at each moment, and the laser annealing system further comprises a relative scanning unit which relatively scans each of the first and second regions with the laser light.

In order to accomplish the aforementioned second object, the third aspect of the present invention is provided. According to the third aspect of the present invention, there is provided a laser-annealed semiconductor film produced by performing the laser annealing process according to the first aspect of the present invention on a noncrystalline semiconductor film. Typically, the noncrystalline semiconductor film is a noncrystalline silicon film. Preferably, the laser-annealed semiconductor film according to the third aspect of the present invention is formed of lateral crystals in substantially the entire area of the laser-annealed semiconductor film. In addition, the laser-annealed semiconductor film according to the third aspect of the present invention may be patterned or unpatterned.

Further, in order to accomplish the aforementioned second object, the fourth aspect of the present invention is also provided. According to the fourth aspect of the present invention, there is provided an unpatterned semiconductor film which is substantially entirely and seamlessly formed of lateral crystals on a substrate. The semiconductor film according to the fourth aspect of the present invention can be produced by using the laser annealing process according to the first aspect of the present invention.

The meaning of the expression “substantially entirely . . . formed of lateral crystals” is as follows.

Although it is possible to transform the noncrystalline semiconductor material into lateral crystals in substantially the entire area of the laser-annealed semiconductor film by using the laser annealing process according to the present invention, portions of granular crystals which are produced in the initial irradiation (the irradiation of the first region in step (a)) and the final irradiation (the irradiation of the second region in step (b) or the irradiation in the final repetition of the step (b) in the case where the step (b) is repeated) and are not reirradiated for transformation into lateral crystals remain. However, the amount of the granular crystals remaining after completion of the laser annealing process according to the first aspect of the present invention is small.

Thus, the expression “substantially entirely . . . formed of lateral crystals” means that the entire area of the semiconductor film except for the above portions of granular crystals remaining after completion of the laser annealing process is formed of lateral crystals only.

Furthermore, in order to accomplish the aforementioned third object, the fifth and sixth aspects of the present invention are provided. According to the fifth aspect of the present invention, there is provided a semiconductor device comprising an active layer obtained by using the laser-annealed semiconductor film according to the third aspect of the present invention. In addition, according to the sixth aspect of the present invention, there is provided a semiconductor device comprising an active layer obtained by using the unpatterned semiconductor film according to the fourth aspect of the present invention. For example, the semiconductor devices according to the fifth and sixth aspects of the present invention are thin-film transistors (TFTs).

Moreover, in order to accomplish the aforementioned third object, the seventh and eighth aspects of the present invention are provided. According to the seventh aspect of the present invention, there is provided an electro-optic device comprising the semiconductor device according to the fifth aspect of the present invention. In addition, according to the eighth aspect of the present invention, there is provided an electro-optic device comprising the semiconductor device according to the sixth aspect of the present invention. The electro-optic devices according to the seventh and eighth aspects of the present invention may be, for example, an electroluminescence (EL) device, a liquid crystal device, an electrophoretic display device, or a sheet computer containing one or more of the EL device, the liquid crystal device, the electrophoretic display device, and the like.

According to the first and second aspects of the present invention, it is possible to selectively melt granular-crystal regions (i.e., the regions of granular crystals) and noncrystalline regions (i.e., the regions of noncrystalline crystals) of a semiconductor film, and increase the crystallinity of the semiconductor film. In addition, since the irradiation in step (b) is performed under such a condition that the already produced lateral crystals are not melted, there is no risk of melting the already produced lateral crystals and changing the crystallinity of the regions of the already produced lateral crystals.

Therefore, when the laser annealing process according to the present invention is used, it is possible to achieve high crystallinity in substantially the entire area of the semiconductor film, and transform a noncrystalline semiconductor film into a seamless laterally-crystallized film which contains almost no granular crystals in substantially the entire area. As explained later with reference to the SEM and TEM photographs of FIGS. 15A and 15B, the present inventors have produced laterally-crystallized films each of which is seamless in substantially the entire area.

Further, when the laser annealing process according to the present invention is used, semiconductor (silicon) films which have high crystallinity and uniformity and are suitable for use as active layers in TFTs can be manufactured at low cost. Therefore, when the semiconductor films according to the present invention are used, it is possible to manufacture semiconductor devices (such as TFTs) superior in the element characteristics (e.g., carrier mobility) and the element uniformity.

Furthermore, since laterally-crystallized films each of which contains almost no granular crystals and is seamless in substantially the entire area can be manufactured according to the present invention, it is unnecessary to contrive to avoid formation of semiconductor devices (such as TFTs) on the edges of irradiated regions. For example, it is unnecessary to relatively scan the laser light on the basis of the design information on the positions of formation of the semiconductor devices (TFTs) so that the edges of the laser beam do not overlap the regions in which the semiconductor devices are to be formed, or to selectively apply the laser light to only the regions of the noncrystalline semiconductor film in which the semiconductor devices are to be formed. Thus, it is possible to stably manufacture, at low cost, semiconductor devices (such as TFTs) superior in the element characteristics (e.g., carrier mobility) and the element uniformity. In addition, when electro-optic devices are produced by using such semiconductor devices, the electro-optic devices can exhibit superior performance, for example, in display quality.

### DESCRIPTION OF THE DRAWINGS

FIG. 1A is a schematic perspective view illustrating an operation of producing lateral crystals and granular crystals by a relative scan with laser light along a line in the x direction at a certain y position.

FIG. 1B is a schematic plan view illustrating examples of relative positions of a lateral-crystal region and granular-crystal regions produced by a relative scan before a shift of the y position and a lateral-crystal region and granular-crystal regions produced by the following relative scan after the shift of the y position.

FIG. 2 is a graph indicating a relationship between the wavelength of laser light and the refractive index n in each of a lateral-crystal region, a granular-crystal region, and a noncrystalline region of a silicon film.

FIG. 3 is a graph indicating a relationship between the wavelength of the laser light and the absorption coefficient in each of the lateral-crystal region, the granular-crystal region, and the noncrystalline region of the silicon film.

FIG. 4 is a graph indicating a relationship between the wavelength of the laser light and the ratio of the absorptance of the granular-crystal silicon to the absorptance of the noncrystalline silicon, and a relationship between the wavelength of the laser light and the ratio of the absorptance of the lateral-crystal silicon to the absorptance of the noncrystalline silicon.

FIG. 5 is a graph indicating a relationship between the surface temperature attained by irradiation of the laser light and the absorbed optical energy, and a relationship between the crystalline state and each of the attained surface temperature and the absorbed optical energy, where the values of the absorbed optical energy at the various surface temperatures are normalized by the value at the attained surface temperature of 2200° C.

FIG. 6 is a graph indicating a relationship between the wavelength of the laser light and the ratio of the absorptance of the lateral-crystal silicon to the absorptance of the noncrystalline silicon in each of the cases where the thicknesses of the silicon film are 50, 100, and 200 nm.

FIG. 7 is a graph indicating the ranges of the wavelength of the laser light and the thickness t of the silicon film in which the attained surface temperatures of the granular-crystal region and the noncrystalline region are approximately 1700 to 2200° C. and the attained surface temperature of the lateral-crystal region is 1400° C. or lower.

FIG. 8 is a graph indicating the ranges of the relative scanning speed of the laser light and the absorption power density in which the attained surface temperature of the noncrystalline region is approximately 2000±200° C.

FIG. 9 is a diagram indicating examples of the distributions of the absorptance, the optical intensity of the laser light with which the film surface is irradiated, the laser-light absorption energy, and the temperature over the surface of the film containing a noncrystalline region, granular-crystal regions, and lateral-crystal regions.

FIG. 10 is a diagram illustrating the construction of a laser annealing system according to an embodiment of the present invention.

FIG. 11 is a diagram illustrating an internal construction of a combined semiconductor-laser light source used in the laser annealing system of FIG. 10.

FIG. 12A is a diagram illustrating a near-field pattern (NFP) and a far-field pattern (FFP) of laser light emitted from a semiconductor laser oscillating in a high-order transverse mode, and is presented for explaining an arrangement for reducing the coherence of laser light in multiple transverse modes.

FIG. 12B is a diagram illustrating an optical waveguide of the semiconductor laser, and is presented for explaining an arrangement for reducing the coherence of the laser light in the multiple transverse modes.

FIGS. 13A, 13B, 13C, 13D, 13E, 13F, 13G, and 13H are cross-sectional views of the structures in respective stages in a process for producing a semiconductor film, a semiconductor device, and an active-matrix substrate according to the embodiment of the present invention.

FIG. 14 is an exploded perspective view of an organic electroluminescence (EL) device as an electro-optic device according to the embodiment of the present invention.

FIG. 15A is an SEM photograph of a surface of the silicon film as a concrete example 1 after the silicon film is substantially entirely laser annealed under the condition 1 according to the embodiment of the present invention.

FIG. 15B is a TEM photograph of a surface of the silicon film as the concrete example 1 after the silicon film is substantially entirely laser annealed under the condition 1 according to the embodiment of the present invention.

FIG. 16A is an SEM photograph of a surface of the silicon film as a comparison example 1 after the silicon film is substantially entirely laser annealed.

FIG. 16B is a TEM photograph of a surface of the silicon film as the comparison example 1 after the silicon film is substantially entirely laser annealed.

FIG. 17 is a TEM photograph of a surface of the silicon film as a comparison example 2 after the silicon film is substantially entirely laser annealed.

FIG. 18 is a graph indicating evaluation results of the Vg-Id characteristics of the TFTs obtained in the concrete example 1 and the comparison example 1.

### DESCRIPTION OF PREFERRED EMBODIMENTS

Laser Annealing Process

It is conventionally known that the noncrystalline silicon (a—Si) and the polycrystalline silicon (poly-Si) exhibit different absorption characteristics with respect to the wavelength of laser light. However, no difference between the granular-crystal silicon and the lateral-crystal silicon, which are both polycrystalline silicon (poly-Si), is conventionally known in the characteristics of absorption of laser light.

The present inventors have investigated the absorption characteristics of the granular-crystal silicon and the lateral-crystal silicon with respect to the wavelength of laser light, and found a difference in the absorption characteristics between the granular-crystal silicon and the lateral-crystal silicon and a laser-irradiation condition under which the lateral crystals do not melt. Further, the present inventors have found that when a silicon film is laser annealed under the above laser-irradiation condition, lateral crystals in the silicon film do not melt, so that only granular-crystal portions and noncrystalline portions in the silicon film are selectively melted and are transformed into lateral crystals without changing the crystallinity of the lateral crystals, and the lateral crystals extend over the entire area of the film. Details of the evaluation performed by the present inventors are explained below.

First, laser annealing of a noncrystalline silicon (a—Si) film is performed by continuously and relatively scanning the a—Si film with laser light L being emitted from one or more GaN-based semiconductor lasers and having an elongated rectangular cross section. In the following explanations, it is assumed that the surface of the substrate is parallel to the x-y plane, the main scanning direction of the laser light is parallel to the x direction, and the sub scanning direction of the laser light is parallel to the y direction.

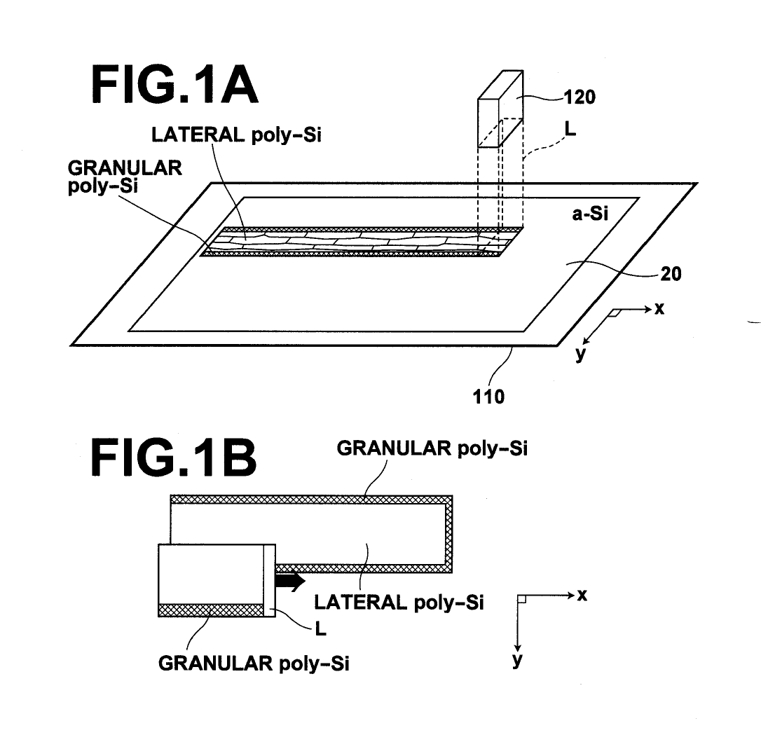

FIG. 1A is a schematic perspective view illustrating an operation of producing lateral crystals and granular crystals by a relative scan with laser light along a line in the x direction at a certain y position. In FIG. 1A, the reference number 20 denotes a noncrystalline semiconductor (a—Si) film to be laser annealed, 110 denotes a stage for placing a substrate, and 120 denotes a laser head. FIG. 1A schematically shows a minimum arrangement for laser annealing the a—Si film 20 with the laser light L, and a situation midway through a relative scan with the laser light L along a line in the x direction at a certain y position. In FIG. 1A, the laser head is magnified for clarity.

As illustrated in FIG. 1A, when a relative scan with the laser light L along a line in the x direction is performed at a certain y position, lateral crystals extending in the main scanning direction x are produced by lateral growth, and granular crystals (poly-Si) having small grain size are produced outside the lateral-crystal region (the region in which the lateral crystals are produced). After the above relative scan along a line, the granular crystals are produced on both sides of the lateral-crystal region, which has a stripelike shape extending in the x direction.

In the example illustrated in FIGS. 1A and 1B, granular crystals are produced along the edges of the region which is directly irradiated with the laser light L. According to the laser-annealing condition, granular crystals are produced in the near-edge portions of the region which is directly irradiated with the laser light L and the regions which are not directly irradiated and to which heat spreads (i.e., the regions which are located immediately outside the irradiated region).

In this specification, in the case where lateral crystals are grown by performing a relative scan with laser light, the region which is annealed by a relative scan with laser light L along a line in the x direction at a certain y position is referred to as a laser-annealed region by a relative scan.

In order to process the entire area of the film, a relative scan with the laser light L along a line in the x direction is repeatedly performed. At this time, the y position of the laser light L is shifted every time a relative scan along a line in the x direction is completed. The y position is shifted in such a manner that the laser annealing after the shift is performed on an area which covers at least a portion of the regions of granular crystals (the granular-crystal regions) produced outside the region of lateral crystals (the lateral-crystal region) before the shift and at least a portion of the noncrystalline portion which has not yet been crystallized before the shift. In addition, the lateral-crystal region may be irradiated with the laser light L by the relative scan after the shift. FIG. 1B is a schematic plan view illustrating examples of relative positions of a lateral-crystal region and granular-crystal regions produced by a relative scan before a shift of the y position and a lateral-crystal region and granular-crystal regions produced by the following relative scan after the shift of the y position. In FIG. 1B, the region irradiated with the laser light L at a certain moment is indicated by the reference L, the granular-crystal regions are indicated by crosshatching, and the lateral-crystal regions are indicated by the non-crosshatched areas inside the crosshatched areas. It is preferable that the region irradiated with the laser light L by the relative scan immediately after the shift of the y position partially overlap the region irradiated with the laser light L by the immediately preceding relative scan (immediately before the shift), as illustrated in FIG. 1B.

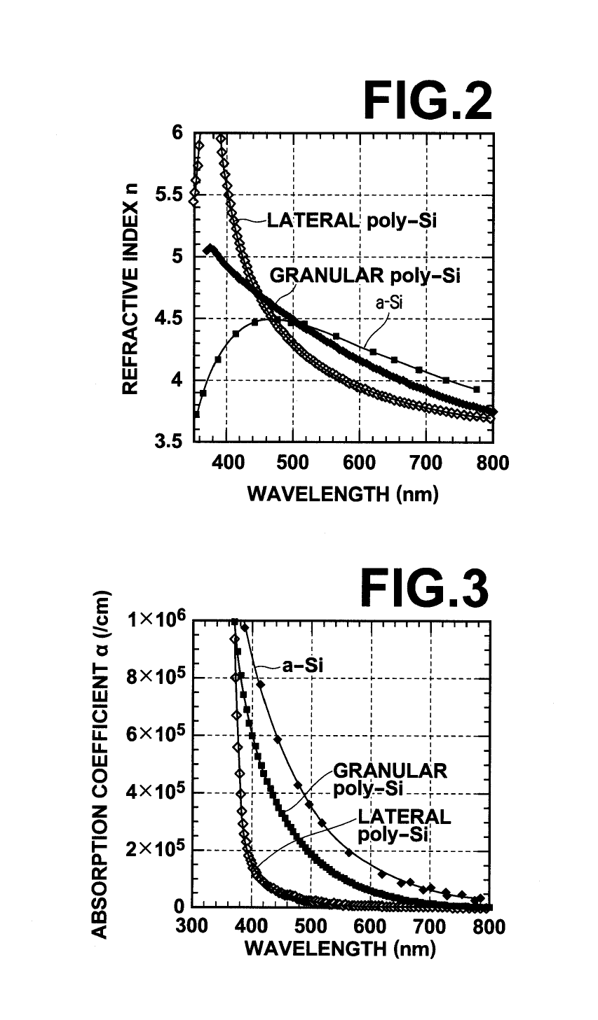

The present inventors have performed measurement of the complex refractive indexes n+ik of the lateral-crystal region (lateral poly-Si), the granular-crystal region (granular poly-Si), and the noncrystalline region (a—Si) for various wavelengths of the measurement light by using an ellipsometer, where k in each complex refractive index is the attenuation coefficient, and ik is the imaginary part of each complex refractive index. The results of the measurement are indicated in FIGS. 2 and 3. FIG. 2 is a graph indicating the relationship between the wavelength and the refractive index n in each of the lateral-crystal region, the granular-crystal region, and the noncrystalline region of the silicon film, and FIG. 3 is a graph indicating the relationship between the wavelength and the absorption coefficient α in each of the lateral-crystal region, the granular-crystal region, and the noncrystalline region of the silicon film. The absorption coefficient α is obtained in accordance with the relationship, α=k/4πλ, where λ is the wavelength of the measurement light.

Next, the present inventors have obtained the absorptances of lateral-crystal silicon, granular-crystal silicon, and noncrystalline silicon in the silicon film at each wavelength.

The output energy from the laser head is attenuated by the loss occurring during propagation through various optical systems mounted in the laser annealing system and the Fresnel reflection at the film surface, and is then absorbed by the film. The optical energy absorbed by the film can be expressed by the formula,
Eab=Ein×a×b,

where Eab is the optical energy absorbed by the film, Ein is the optical energy of light applied to the film, a is the proportion of the amount of light absorbed by the film, and b is the proportion of the amount of light entering the film.

In the above formula, a×b corresponds to the absorptance, which is the proportion of the optical energy absorbed by the film to the optical energy of light applied to the film.

The proportion a of the amount of light absorbed by the film is obtained by the formula,
a=exp^{-αt},
where α is the absorption coefficient, and t is the thickness of the film. In the measurement performed by the present inventors, the thickness t is 50 nm, which is a common thickness in the production of polysilicon TFTs by crystallization using laser annealing.

The proportion b of the amount of light entering the film is obtained by the formula,
b=1−((1−n)/(1+n))²,
where n is the refractive index. That is, the proportion b of the amount of light entering the film is the quantity obtained by subtracting the amount of the loss caused by the Fresnel reflection at the film surface from the amount of laser light emitted from the laser head.

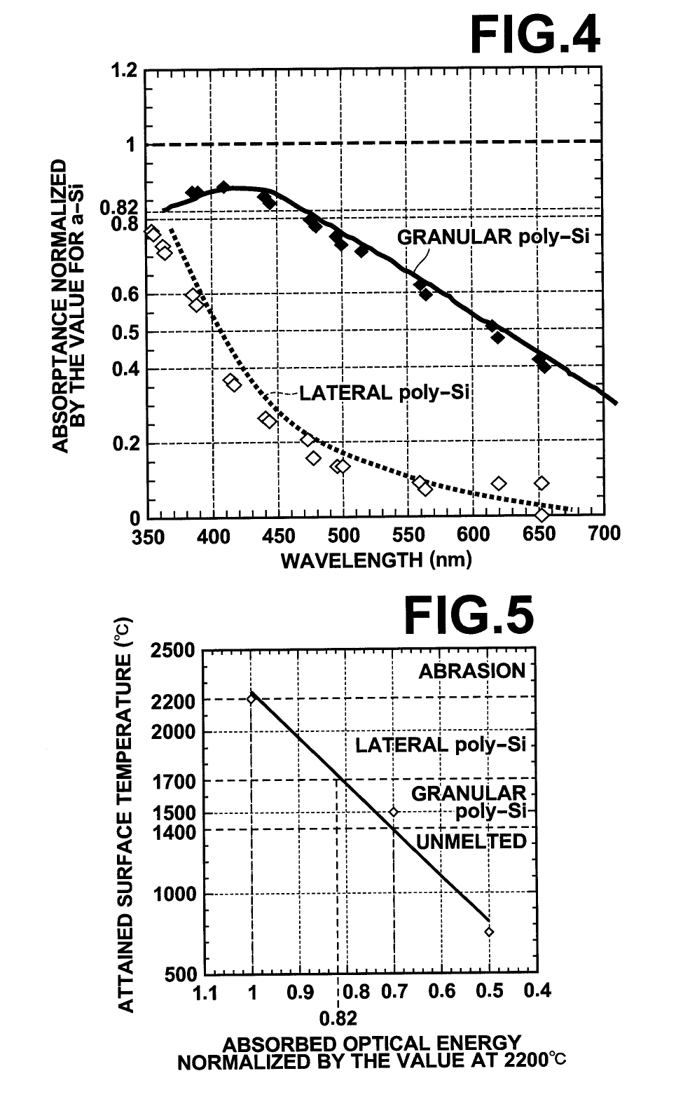

Further, the present inventors have obtained for each wavelength of the laser light the ratio of the absorptance of the granular-crystal silicon (granular poly-Si) to the absorptance of the noncrystalline silicon (a—Si) and the ratio of the absorptance of the lateral-crystal silicon (lateral poly-Si) to the absorptance of the noncrystalline silicon (a—Si). That is, the former ratio is the absorptance of the granular-crystal silicon relative to the absorptance of the noncrystalline silicon and is hereinafter referred to as the absorptance ratio of the granular-crystal silicon, and the latter ratio is the absorptance of the lateral-crystal silicon relative to the absorptance of the noncrystalline silicon and is hereinafter referred to as the absorptance ratio of the lateral-crystal silicon. FIG. 4 is a graph indicating the relationship between the wavelength of the laser light and the relative absorptance of the granular-crystal silicon and the relationship between the wavelength of laser light and the relative absorptance of the lateral-crystal silicon, which are obtained as above. FIG. 4 shows that there is a great difference between the granular-crystal silicon and the lateral-crystal silicon in the absorption characteristics with respect to the wavelength of the laser light.

As FIGS. 2 to 4 show, the characteristic of the granular-crystal silicon (granular poly-Si) having small grain size is intermediate between the characteristic of the noncrystalline silicon (a—Si) and the characteristic of the lateral-crystal silicon (lateral poly-Si). As far as the present inventors know, the difference in the absorption characteristics between the granular-crystal silicon and the lateral-crystal silicon has not been reported before.

As indicated in FIG. 4, in the range of wavelengths shorter than 350 nm, no substantial difference is observed in the absorption characteristics between the granular-crystal silicon and the lateral-crystal silicon, and both of the granular-crystal silicon and the lateral-crystal silicon exhibit the absorptance as high as 0.7 to 0.9 times the absorptance of the noncrystalline silicon. In the range of wavelengths of approximately 350 nm or longer, the absorptances of both of the granular-crystal silicon and the lateral-crystal silicon relative to the noncrystalline silicon decrease with increase in the wavelength. However, the absorptance of the lateral-crystal silicon more greatly decreases than the absorptance of the granular-crystal silicon, and the decrease in the absorptance of the lateral-crystal silicon begins at the shorter wavelength than the decrease in the absorptance of the granular-crystal silicon. Therefore, in the range of wavelengths of 350 to 650 nm, the difference between the absorptances of the granular-crystal silicon and the lateral-crystal silicon relative to the noncrystalline silicon is great.

Although FIG. 4 shows the absorptances relative to the absorptance of the noncrystalline silicon (a—Si), as indicated in FIG. 3, all of the absolute values of the absorptances of the lateral-crystal silicon, the granular-crystal silicon, and the noncrystalline silicon are extremely small in the range of wavelengths of 500 nm or greater. Therefore, it is preferable that the wavelength of the laser light for use be determined to be in a range in which the difference between the absorptances of the lateral-crystal silicon and the granular-crystal silicon is great, and the absolute values of the absorptances of the granular-crystal silicon and the noncrystalline silicon are not so small.

For example, in the case where the thickness t is 50 nm, when laser light in the range of wavelengths of 350 to 500 nm (preferably 350 to 400 nm) is used, it is possible to perform laser annealing so as to melt granular-crystal regions and noncrystalline regions and transform the granular-crystal regions and the noncrystalline regions into lateral crystals without melting lateral-crystal regions which have been already produced.

The excimer laser is the laser light which is currently widely used in laser annealing. Since the excimer laser is ultraviolet laser having the wavelength of 300 nm or shorter, the absorptances of all of the lateral-crystal regions, the granular-crystal regions, and the noncrystalline regions are high, and there is no difference between the absorption characteristics of the lateral-crystal regions, the granular-crystal regions, and the noncrystalline regions.

The laser light used in the techniques disclosed in the aforementioned JPP 2005-072183 (US 20060051943), JPP 2005-217209 (US 20050169330), JPP 2004-152978, JPP 2005-259809, and JPP 2004-297055 are the second harmonics outputted from solid-state lasers in the range of wavelengths of 500 to 550 nm. It appears from FIG. 4 that the difference in the absorption characteristics between the granular-crystal silicon and the lateral-crystal silicon is great in the range of wavelengths of 500 to 550 nm. However, since the absorptance of the noncrystalline silicon is very low in this wavelength range as indicated in FIG. 3, the difference in the absorption characteristics between the granular-crystal silicon and the lateral-crystal silicon is actually not so great in this wavelength range.

That is, the laser light conventionally used in the laser annealing, i.e., the laser light in the range of wavelengths of 300 nm or shorter, or 500 to 550 nm, does not exhibit a great difference in the absorption characteristic between the lateral-crystal regions and the granular-crystal regions. In addition, since both of the lateral-crystal regions and the granular-crystal regions are regions of polycrystalline silicon, it has been conventionally considered that the absorption characteristics of the lateral-crystal regions and the granular-crystal regions are not greatly different. However, the present inventors have shown that a wavelength range in which the absorption characteristics of the lateral-crystal regions and the granular-crystal regions are greatly different exists.

Japanese Unexamined Patent Publication No. 2004-064066 (hereinafter referred to as JPP 2004-064066) discloses a laser annealing system using one or more GaN-based simulation lasers (having the oscillation wavelength of 350 to 450 nm). JPP 2004-064066 also discloses (for example, in the paragraph No. 0127) an irradiation condition that the relative scanning speed is 3000 mm/s, and the optical power density at the surface of the noncrystalline silicon film is 600 mJ/c m³. However, the relationship between the crystalline state and the absorptance or the like is not considered in JPP 2004-064066.

The melting temperature of the monocrystalline silicon (c—Si) is approximately 1400° C., and the melting temperature of the noncrystalline silicon (a—Si) is approximately 1200° C. Therefore, in order to melt the granular-crystal region and the noncrystalline region, it is preferable that the surface temperature of the granular-crystal region and the noncrystalline region attained by irradiation with the laser light be approximately 1400° C. or higher.

The present inventors have performed laser annealing of noncrystalline silicon films by using GaN-based semiconductor lasers having the oscillation wavelength of 405 nm, relatively scanning with laser light at the relative scanning speed of 0.01 m/sec, and varying the amount of light outputted from the laser head. Then, the present inventors have observed growth or nongrowth of lateral crystals in the center of the beam spot of the laser light by SEM and TEM, and obtained, on the basis of the results of the observation, a value of approximately 1700° C. as the attained surface temperature necessary for growth of the lateral crystals. In addition, the present inventors have found that partial abrasive exfoliation of the film can occur when the attained surface temperature becomes approximately 2200° C. or higher. Therefore, in order to transform the granular-crystal region and the noncrystalline region into lateral crystals, it is preferable that the surface temperature attained by irradiation with the laser light (the attained surface temperature) be approximately 1700 to 2200° C. The surface temperature attained by irradiation with the laser light is the instantaneous temperature of the film surface which is irradiated with the laser light.

The attained surface temperature can be theoretically obtained on the basis of the amount of light entering the silicon film and the absorptance of the silicon film. The amount of light entering the silicon film can be obtained by subtracting the loss occurring during propagation through various optical systems mounted in the laser annealing system and the loss caused by the Fresnel reflection at the film surface from the amount of light outputted from the laser head.

The irradiation energy necessary for attaining a desired surface temperature can be roughly expressed by the formula,
E1=E2+E3+E4,
where E1 is the irradiation energy, E2 is the melting energy, E3 is the energy necessary for raising to the desired temperature, and E4 is the heat dissipation energy. Each of the irradiation energy E1, the melting energy E2, the energy E3 necessary for raising to the desired temperature, and the heat dissipation energy E4 can vary with time and temperature. The melting energy E2 is the energy necessary for melting the irradiated portion of the film.

For reference, examples of calculation of the melting energy E2 and the energy E3 necessary for raising to desired temperature for an adiabatic model in which a rectangular parallelepiped with the dimensions of 1 micrometer X 1 micrometer×50 nm is heated are indicated below. In the following examples, the desired temperature is assumed to be 1400° C.

The energy E2 necessary for melting Si in the above volume can be calculated as,
E2=Eᵤₘ×nₛᵢ=46×10³×((2.32 g/cm³)×(10⁻⁶×10⁻⁶×50×10⁻⁹ m³)/28)=1.9×10⁻¹⁰(J),
where Eᵤₘ is the unit melting energy, and nₛᵢ is the mole value of Si in the volume.

In addition, the energy E3 necessary for raising the temperature of Si in the above volume to the desired temperature can be calculated as follows.
E3=C×Mₛᵢ=770 J/kg K×(2.32 g/cm³×(10⁻⁶×10⁻⁶×50×10⁻⁹ m³))×1400° C.=1.3×10⁻¹⁰(J),
where C is the specific heat, and M_{Si} is the mass of Si in the volume.

FIG. 5 shows a relationship between the surface temperature attained by irradiation of laser light and the absorbed optical energy, and a relationship between the crystalline state and each of the attained surface temperature and the absorbed optical energy, where the values of the absorbed optical energy at the various surface temperatures are normalized by the value at the attained surface temperature of 2200° C. Although the noncrystalline silicon melts at the temperature of approximately 1200° C. or higher, the range of the attained surface temperature of 1400° C. or lower, in which the lateral crystals and the granular-crystal regions do not melt, is indicated as “Unmelted” in FIG. 5. In addition, the range of the attained surface temperature of 1700 to 2200° C. (in which the lateral crystals grow) and the range of the attained surface temperature of 2200° C. or higher (in which partial abrasive exfoliation of the film can occur) are also indicated in FIG. 5.

Even when the a—Si film 20 is irradiated with light having a uniform optical energy distribution, the amount of absorbed optical energy is different according to the crystalline state, so that the surface temperature attained by irradiation of the laser light is also different according to the crystalline state. FIG. 5 shows that lateral crystals can grow under the condition that the normalized absorbed optical energy is 0.82 or greater, and the granular crystals do not melt under that the normalized absorbed optical energy is 0.70 or smaller.

When optical energy is supplied to (absorbed by) the granular-crystal region and the noncrystalline region so that the surface temperature attained by irradiation of laser light is approximately 1700 to 2200° C., it is possible to melt the granular-crystal region and the noncrystalline region and transform the granular-crystal region and the noncrystalline region into lateral crystals without melting lateral crystals which have been already produced.

In the case where all of the lateral-crystal region, the granular-crystal region, and the noncrystalline region are irradiated with laser light under an identical irradiation condition, when the ratio of the absorptance A_{G} of the granular-crystal silicon (granular poly-Si) to the absorptance A_{N} of the noncrystalline silicon (a—Si) is 0.82 or greater and the ratio of the absorptance A_{L} of the lateral-crystal silicon (lateral poly-Si) to the absorptance A_{N} of the noncrystalline silicon (a—Si) is 0.70 or smaller, it is possible to make the ratio of the absorbed optical energy in the lateral-crystal region, the granular-crystal region, and the noncrystalline region (0.70 or smaller):(0.82 to 1.0):1.0.

That is, in the case where the a—Si film 20 is a noncrystalline silicon film, it is preferable to perform laser annealing so that the absorptance A_{L} of the lateral-crystal region, the absorptance A_{G} of the granular-crystal region, and the absorptance A_{N} of the noncrystalline region to the laser light satisfy the following conditions (1) and (2).
0.82≦(A_{G}/A_{N})≦1.0 (1)
(A_{L}/A_{N})≦0.70 (2)

Further, in order to stably perform the laser annealing so as not to melt the lateral crystals, it is more preferable to perform laser annealing so that the absorptance A_{L} of the lateral-crystal region, the absorptance A_{G} of the granular-crystal region, and the absorptance A_{N} of the noncrystalline region to the laser light satisfy the following conditions (1A) and (2).
0.85≦(A_{G}/A_{N})≦1.0 (1A)
(A_{L}/A_{N})≦0.70 (2)

In FIG. 4, the levels of the absorptance ratios equal to 0.7 and 0.82 are respectively indicated by dashed lines. FIG. 4 shows that in the case where the thickness of the silicon film is 50 nm, the absorptance ratio of the granular-crystal silicon (i.e., the ratio of the absorptance of the granular poly-Si to the absorptance of the a—Si) is 0.82 or greater, and the absorptance ratio of the lateral-crystal silicon (i.e., the ratio of the absorptance of the lateral poly-Si to the absorptance of the a—Si) is 0.70 or smaller, in the range of wavelengths of 360 to 450 nm.

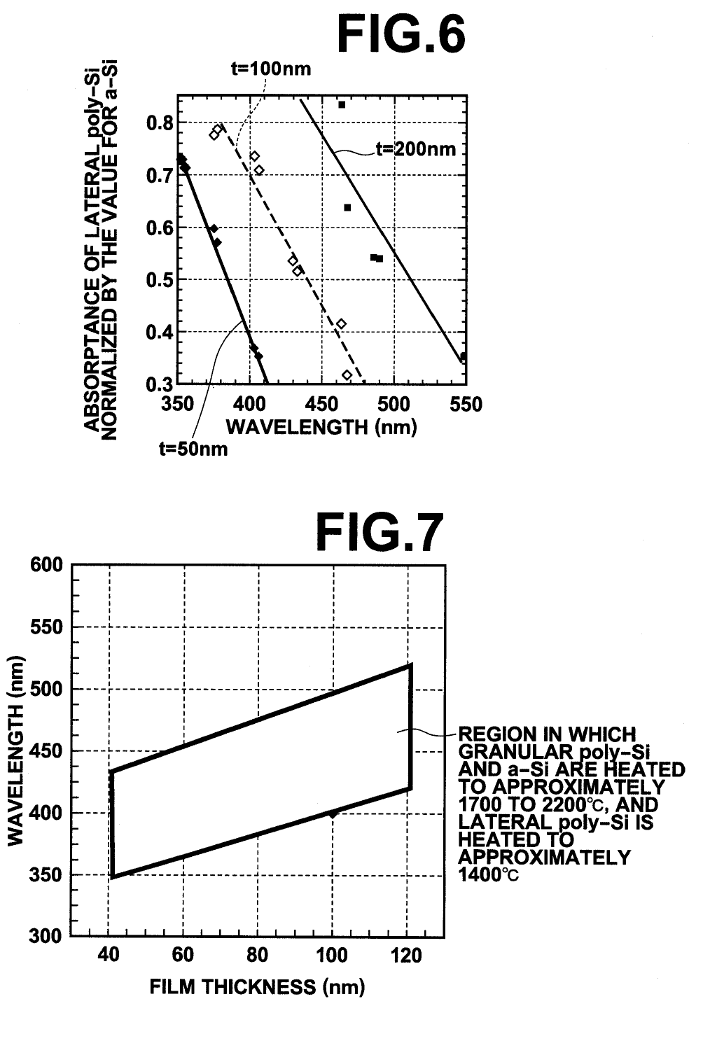

The absorptance to laser light varies with the thickness t of the silicon film. The present inventors have obtained a relationship between the wavelength of the laser light and the absorptance ratio of the lateral-crystal silicon (i.e., the ratio of the absorptance of the lateral poly-Si to the absorptance of the a—Si) for each of the film thicknesses, 50, 100, and 200 nm. The result is indicated in FIG. 6.

FIG. 6 shows that the wavelength at which the absorptance ratio of the lateral-crystal silicon (i.e., the ratio of the absorptance of the lateral poly-Si to the absorptance of the a—Si) falls to 0.7 varies with the film thickness. In addition, although not shown, the wavelength at which the absorptance ratio of the granular-crystal silicon (i.e., the ratio of the absorptance of the granular poly-Si to the absorptance of the a—Si) increases to 0.82 also varies with the film thickness.

In the case where polysilicon TFTs are produced by crystallization using laser annealing, when the film thickness t is greater than 120 nm, formation of the TFTs becomes difficult and leakage current increases. On the other hand, when the film thickness t is smaller than 40 nm, the thicknesses of the active layers of the TFTs becomes too small, so that the reliability of the TFTs is lowered. Therefore, it is preferable that the film thickness t for use in the TFTs satisfy the following condition (4).
40 nm≦film thickness t≦120 nm (4)
As mentioned before, in the case where polysilicon TFTs are produced by using silicon films crystallized by laser annealing, the most common thickness of the silicon film is approximately 50 nm.

FIG. 7 is a graph indicating the ranges of the wavelength of the laser light and the thickness t of the silicon film in which the attained surface temperatures of the granular-crystal region and the noncrystalline region are approximately 1700 to 2200° C. and the attained surface temperature of the lateral-crystal region is 1400° C. or lower.

Although the wavelength at which the absorptance ratio of the lateral-crystal silicon (i.e., the ratio of the absorptance of the lateral poly-Si to the absorptance of the a—Si) falls to 0.7 varies with the film thickness, the laser annealing should be performed under the following condition (3),
0.8t+320 nm≦λ≦0.8t+400 nm, (3)
where λ is the wavelength of the laser light L and t is the film thickness.

When the film thickness satisfies the condition (4), and the wavelength of the laser light is within the range of 350 to 500 nm, and preferably 350 to 490 nm, it is possible to perform laser annealing so as to melt the granular-crystal region and the noncrystalline region and transform the granular-crystal region and the noncrystalline region into lateral crystals without melting lateral crystals which have been already produced.

As explained before, in order to transform the granular-crystal region and the noncrystalline region into lateral crystals, it is necessary that the attained surface temperature of the granular-crystal region and the noncrystalline region be within the range of approximately 1700 to 2200° C. The present inventors have performed laser annealing at various temperatures within the above range, and found that curved lateral crystals can be produced in the granular-crystal region when the attained surface temperature is relatively low within the above range. The curved lateral crystals are considered to be produced because the granular crystals behave as nuclei, so that lateral crystals tend to grow in directions not parallel to the main scanning direction of the laser light (e.g., in directions different from the main scanning direction by 5 to 45 degrees), and the lateral crystals also tend to grow so as to align in the main scanning direction. In order to suppress variations in the element characteristics, it is preferable that the orientations of almost all the lateral crystals be aligned in the entire area of the film.

The present inventors have found that when laser annealing is performed under the condition that the attained surface temperature of the granular-crystal region and the noncrystalline region is 2000±200° C., the granular crystals instantaneously melt, and the growth of the lateral crystals from the granular crystals as the nuclei is suppressed, so that it is possible to align the orientations of almost all the lateral crystals in the entire area of the film. Further, the present inventors have found that the directions of growth of the lateral crystals can be aligned in the entire area of the film so that the angles between the main scanning direction of the laser light and the directions of growth are 5 degrees or smaller.

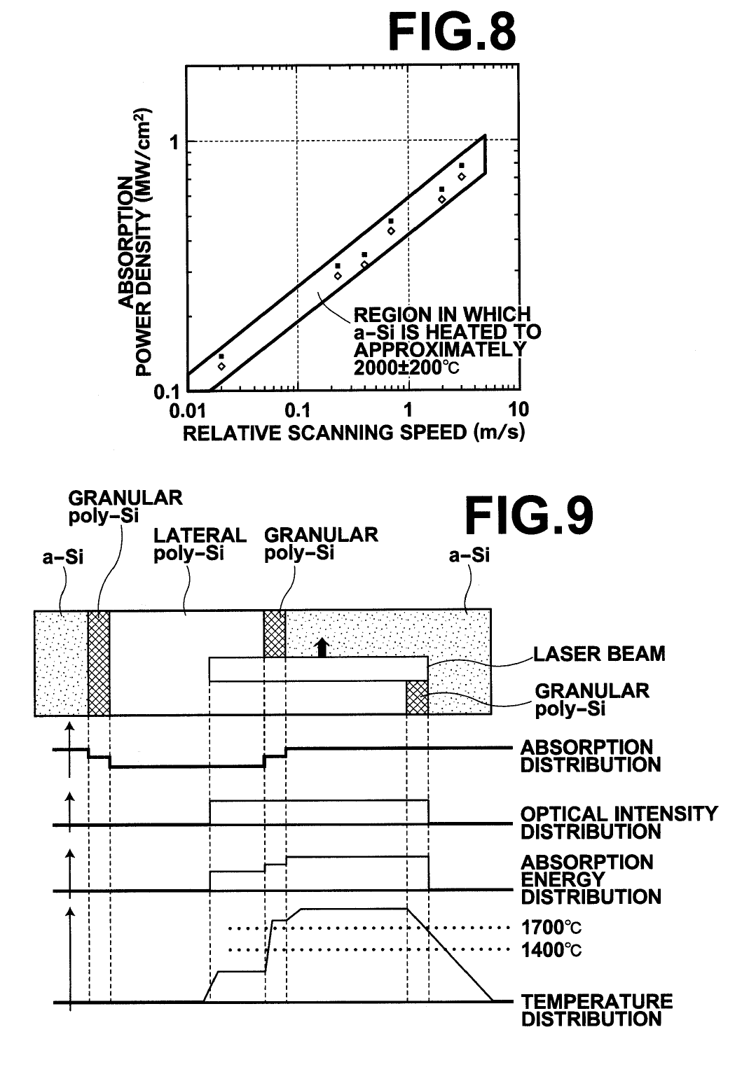

FIG. 8 is a graph indicating the ranges of the relative scanning speed of the laser light and the absorption power density in which the attained surface temperature of the noncrystalline region is approximately 2000±200° C. As indicated in FIG. 8, it is preferable that the laser annealing be performed so that the relative scanning speed v (m/sec) of the laser light and the absorption power density P (MW/cm²) in the noncrystalline region satisfy the following condition (5).
0.44v^{0.34143}≦P≦0.56v^{0.34143} (5)

Conventionally, in the field of the SOI (Silicon on Insulator) technology, it is reported that the crystal growth rate of silicon not exceeding 1 cm/sec can be expressed as
V=V0×exp(−Ea/kT),
where V is the solid-phase growth rate (cm/sec) in the transformation from a—Si into poly-Si, k is the Boltzmann constant, T is the annealing temperature (K), V0 is a coefficient equal to 2.3×10⁸ to 3.1×10⁸ cm/sec, and Ea is the activation energy, which is equal to the vacancy formation energy in c—Si (crystalline silicon), and is specifically 2.68 to 2.71 eV.

The present inventors have confirmed that the growth rate of the lateral crystals in the laser annealing according to the present invention can also be expressed by the same formula as the above crystal growth rate. Since the upper limit of the annealing temperature in the noncrystalline region is 2200° C. as mentioned before, the upper limit of the growth rate of the lateral crystals is 8 m/sec.

In the case where the wavelength of laser light used in laser annealing is selected so that the ratio of the absorptance A of the granular-crystal silicon to the absorptance A_{N} of the noncrystalline silicon is 0.82 or greater and the ratio of the absorptance A_{L} of the lateral-crystal silicon to the absorptance A_{N} of the noncrystalline silicon is 0.70 or smaller, and all of the lateral-crystal regions, the granular-crystal regions, and the noncrystalline regions are irradiated with laser light for laser annealing under an identical irradiation condition so that the attained surface temperatures of the granular-crystal regions and the noncrystalline regions are approximately 1700 to 2200° C. and the attained surface temperature of the lateral-crystal regions is approximately 1400° C., the distributions of the absorptance, the optical intensity of the laser light with which the film surface is irradiated, the laser-light absorption energy, and the temperature of the film containing the noncrystalline regions, the granular-crystal regions, and the lateral-crystal regions become, for example, as schematically indicated in FIG. 9. The temperature of the film is different from the attained surface temperatures. FIG. 9 also schematically shows the crystalline states of areas of the semiconductor film and the position and the main scanning direction of the laser beam with which the surface is relatively scanned.

Since the absorptances of the noncrystalline regions, the granular-crystal regions, and the lateral-crystal regions are different although the intensity distribution of the irradiation light over the surface of the film containing the noncrystalline regions, the granular-crystal regions, and the lateral-crystal regions is uniform, the optical energy absorbed in the noncrystalline regions, the granular-crystal regions, and the lateral-crystal regions are different. Therefore, the granular-crystal regions and the noncrystalline regions are heated to the temperature at which the granular-crystal regions and the noncrystalline regions melt, and the temperature of the lateral-crystal regions which have been already produced is suppressed at such a level that the lateral-crystal regions are not remelted.

As illustrated in FIG. 1A, when the first relative scan with the laser light L along a line in the x direction is performed at a certain y position, granular crystals are produced on both sides of a lateral-crystal region which has a stripelike shape extending in the x direction. According to the conventional technique, even in the second relative scan performed after the y position is shifted, granular crystals are also produced on both sides of another lateral-crystal region produced by the second relative scan.

On the other hand, according to the present invention, when the lateral-crystal region produced by a first relative scan with laser light L is reirradiated by a second relative scan with the laser light L, the lateral-crystal region do not melt, and the temperature of the reirradiated lateral-crystal region does not reach the level at which granular crystals are produced. Therefore, in the second relative scan performed after the y position is shifted, granular crystals are produced on only one side of the lateral-crystal region produced by the second relative scan on which a noncrystalline region exists. That is, according to the present invention, the second relative scan can transform the granular-crystal region on one side of the lateral-crystal region produced by the first relative scan into lateral crystals, and does not newly produce granular crystals in the lateral-crystal region produced by the first relative scan. Therefore, when a relative scan with the laser light L along a line in the x direction at a certain y position and a shift of the y position after the relative scan are repeated, the film can be substantially entirely transformed into lateral crystals.

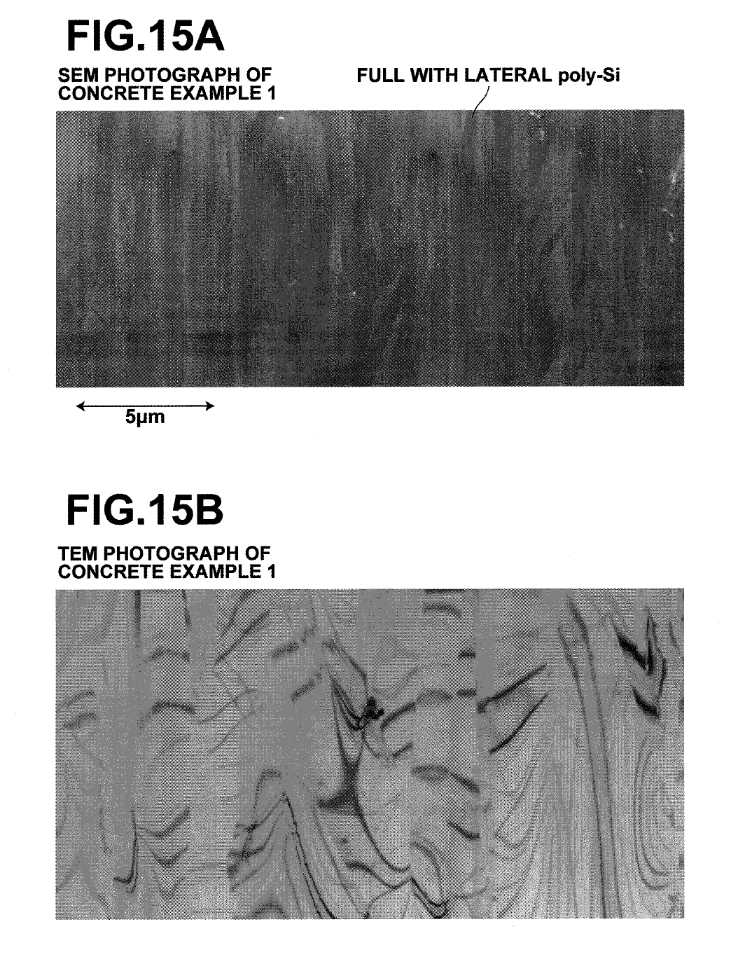

As explained above, according to the present invention, it is possible to obtain a substantially entirely laterally-crystallized film, the entire area of which is substantially formed of lateral crystals. The laterally-crystallized film is a polysilicon film formed of stripelike crystal grains extending in the main scanning direction of the laser light. The laterally-crystallized film can be effectively regarded as an approximately monocrystalline film (pseudo monocrystalline film). The substantially entirely laterally-crystallized film is a film the entire area of which is substantially formed of lateral crystals. The present inventors have produced a substantially entirely laterally-crystallized film formed of crystal grains having lengths of approximately 5 micrometers or greater in the main scanning direction and widths of 0.2 to 2 micrometers. (See the SEM and TEM photographs of FIGS. 15A and 15B indicating the surface of the film as the concrete example 1.)

Although the laser-annealed semiconductor film 20 in the cases explained above is a silicon film, it is possible to produce a substantially entirely laterally-crystallized film of any other material by performing laser annealing under such an irradiation condition as to melt granular-crystal regions and noncrystalline regions and not to melt lateral-crystal regions. That is, when each relative scan of the semiconductor film is performed under such an irradiation condition, it is possible to transform the granular-crystal regions and the noncrystalline regions into lateral crystals without melting lateral crystals already produced by previous relatively scans or changing the crystallinity of the lateral crystals already produced by previous relatively scans, so that a substantially entirely laterally-crystallized film can be finally obtained.

As mentioned before, in the laser annealing process for performing laser annealing of a semiconductor film made of a noncrystalline semiconductor material according to the first aspect of the present invention, laser annealing of a first region of the semiconductor film is performed in step (a) by irradiating the first region with laser light under a condition for growing lateral crystals in the first region; laser annealing of a second region of the semiconductor film is performed in step (b) by irradiating the second region with the laser light under such a condition that granular crystals and the noncrystalline semiconductor material in the second region are transformed into lateral crystals without melting lateral crystals produced in the semiconductor film by previous irradiation with the laser light, where the second region is shifted from a region of the semiconductor film which has been already irradiated with the laser light and includes at least a part of granular crystals which are produced by previous irradiation with the laser light and at least a part of the noncrystalline semiconductor material in the semiconductor film which has not yet been crystallized.

The material of which the semiconductor film is made is not specifically limited, and may be, for example, silicon, germanium, silicon/germanium, or the like.

As mentioned before, in the laser annealing process according to the present invention, it is preferable that the region irradiated with the laser light by each relative scan after a shift of the y position partially overlap the region irradiated with the laser light by the immediately preceding relative scan before the shift, as illustrated in FIG. 1B.

The manner of the partial overlapping of the irradiated areas is not specifically limited. When all the granular-crystal regions produced by one or more previous relatively scans with laser light are irradiated by a following relative scan, all the granular-crystal regions are transformed into lateral crystals, and a new lateral-crystal region can be produced by the following relative scan without producing a granular-crystal region along the boundary between the lateral-crystal regions produced by the one or more previous relatively scans and the lateral-crystal region produced by the following relative scan.

According to the use of the semiconductor film semiconductor film, the granular-crystal regions between lateral-crystal regions are allowed to remain. Even in such a case, when one percent or more of granular-crystal regions v are irradiated by a following relative scan, the granular-crystal region can be partially transformed into lateral crystals, so that the lateral-crystal region can be enlarged. When the proportion of the granular-crystal regions irradiated by the following relative scan is greater, a greater lateral-crystal region is formed on the semiconductor film. Therefore, it is possible to perform each relative scan so that a greater proportion of the granular-crystal region produced by one or more previous relative scans is irradiated by each relative scan specifically, the proportion of 50% or greater is preferable.

According to the laser-annealing condition, granular crystals can be produced in one or more near-edge portions of the directly irradiated region, and/or in one or more regions which are not directly irradiated with the laser light and to which heat spreads (i.e., one or more regions which are located immediately outside the irradiated region).

Consider a case where granular crystals are produced, by the first relative scan along a line in the x direction, in one or more regions which are not directly irradiated with the laser light and to which heat spreads (i.e., one or more regions which are located immediately outside the irradiated region), and thereafter the granular crystals produced by the first relative scan are directly irradiated with laser light by the next relative scan along a line in the x direction which is performed after the y position is shifted. In such a case, part of the granular crystals can be transformed into lateral crystals even when the region irradiated by the first relative scan does not overlap the region irradiated by the second relative scan. However, since the position of the irradiated region can deviate from the region in which the granular crystals are produced, in the case where a semiconductor film is laser annealed by repeating a relative scan with the laser light along a line in the x direction at a certain y position and a shift of the y position after the relative scan, it is preferable to perform each relatively scan so that the region irradiated by the relative scan partially overlaps the region irradiated by the preceding relative scan.

In the laser annealing process according to the present invention, it is preferable to use continuous-wave laser light. In the case where pulsed-wave laser light is used, application of the laser light is periodically intermits even while the laser head is activated. On the other hand, in the case where continuous-wave laser light is used, the laser light is continuously applied to the semiconductor film while the laser head is activated, so that it is possible to finely and uniformly process the semiconductor film and grow lateral crystals having greater grain size. In addition, in consideration of the wavelength range suitable for use in the laser annealing according to the present invention, it is preferable to use laser light emitted from one or more semiconductor lasers.

Although the laser light is applied to the semiconductor film by relatively scanning the semiconductor film with the laser light in the example explained above, the present invention can be applied to laser annealing performed under a condition that lateral crystals grow, even when the relative scanning is not performed.

For example, consider a case where application of laser light to a rectangular area of the semiconductor film under the aforementioned irradiation condition according to the present embodiment and reduction of the width of the rectangular area in a direction are repeated without changing a centerline of the rectangular area. In this case, cooling begins from the periphery of the initial rectangular area, and a temperature slope is produced between the centerline and the outside of the rectangular area, so that lateral crystals extending from the centerline to the outside can grow. In the above case, the region which is annealed by the sequence of the repeated application of the laser light is a region laser annealed according to the present invention. At this time, similar to the case where the relative scanning is performed, granular crystals are also produced outside the region in which the lateral crystals are produced.

However, since the repeated application of the laser light is necessary for each laser-annealed region, and stepwise reduction of the irradiation area is required to be performed, for example, by different photomasks or the like, the semiconductor film cannot be continuously processed, so that the laser annealing process is inefficient. In addition, it is difficult to uniformly process the entire area of the semiconductor film.

Therefore, in the laser annealing according to the present invention, it is preferable to perform the laser annealing of a semiconductor film by relatively scanning the semiconductor film with laser light. In this case, lateral crystals grow along the main scanning direction of the laser light, so that it is possible to continuously grow the lateral crystals, and efficiently process the entire area of the semiconductor film. In addition, since the entire area of the semiconductor film can be continuously and finely processed, it is possible to obtain a substantially entirely laterally-crystallized film which is superior in uniformity.

When the laser annealing process according to the present invention is used, it is possible to manufacture at low cost a semiconductor film having high crystallinity and uniformity and being suitable for use as active layers in the TFTs and the like. Further, when the semiconductor film produced by the laser annealing process according to the present invention is used, it is possible to manufacture semiconductor devices (such as TFTs) which are superior in element characteristics (such as carrier mobility) and element uniformity.

Since a laterally-crystallized film being seamless and having almost no granular-crystal region in the entire area can be produced by the laser annealing process according to the present invention, it is unnecessary to contrive to relatively scan the laser light on the basis of the design information on the TFT formation positions so that the edges of the laser beam do not overlap the regions in which the TFTs are to be formed, or to selectively apply the laser light to only the regions of the noncrystalline semiconductor film in which the TFTs are to be formed. Therefore, it is possible to stably manufacture at low cost semiconductor devices such as TFTs which are superior in element characteristics (such as carrier mobility) and element uniformity, so that electro-optic devices using such semiconductor devices exhibits superior performance, e.g., display quality.

Laser Annealing System

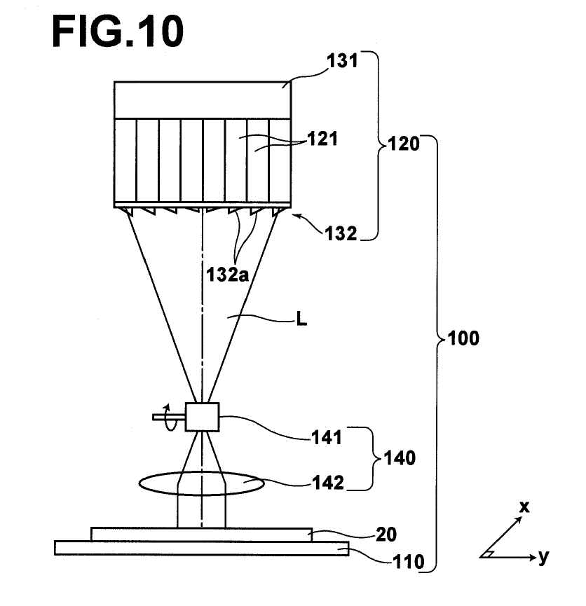

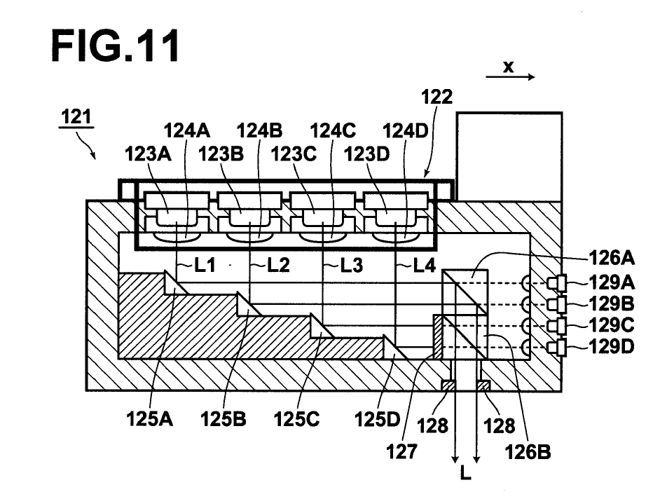

Hereinbelow, a construction of a laser annealing system according to an embodiment of the present invention is explained with reference to FIGS. 10, 11, 12A, and 12B. FIG. 10 shows the entire construction of the laser annealing system according to the embodiment, and FIG. 11 shows an internal construction of a combined semiconductor-laser light source (combined laser-light sources) used in the laser annealing system of FIG. 10.

The laser annealing system 100 comprises a stage 110, a laser head 120, and an optical scanning system 140. A semiconductor film 20 (e.g., a noncrystalline silicon film) to be laser annealed is placed on the stage 110, the laser head 120 outputs laser light L, and the optical scanning system 140 relatively scans the laser light L.

Specifically, the optical scanning system 140 is arranged to relatively scan the laser light L in the x direction (the main scanning direction). In addition, the stage 110 is arranged to be movable in the y direction by use of a stage moving mechanism (not shown) so that the y position of the laser light L on the semiconductor film 20 can be shifted (i.e., the laser light is relatively moved in the y direction (the sub scanning direction). Thus, in the construction of FIG. 10, the stage 110 and the optical scanning system 140 constitute a relative scanning unit, which realizes the relative scanning of the semiconductor film 20 with the laser light L.

In brief outline, the laser head 120 is constituted by a plurality of combined laser-light sources 121, which are closely arranged on a water-cooling heat sink 131.

As illustrated in FIG. 11, each of the combined laser-light sources 121 comprises an LD unit 122, which contains four LD packages 123A to 123D and four collimator lenses 124A to 124D. In each of the LD packages 123A to 123D, a multiple-transverse-mode semiconductor laser diode (LD) emitting continuous-wave laser light is built in as a laser-light source. Thus, the four LD packages 123A to 123D output laser beams L1 to L4. In the LD unit 122, the four collimator lenses 124A to 124D are arranged in correspondence with the four LD packages 123A to 123D, and respectively collimate the laser beams L1 to L4.

In the combined laser-light sources 121, the four LD packages 123A to 123D are arranged in the x direction (i.e., the horizontal direction in FIG. 11).

The combined laser-light sources 121 further comprises four reflection mirrors 125A to 125D and two polarization beam splitters (PBSs) 126A and 126B. The reflection mirrors 125A to 125D are arranged in correspondence with the LD packages 123A to 123D, and respectively reflect the laser beams L1 to L4. After the laser beams L1 and L2 are reflected by the reflection mirrors 125A and 125B, the reflected laser beams L1 and L2 enter the polarization beam splitter (PBS) 126A. In addition, after the laser beams L3 and L4 are reflected by the reflection mirrors 125C and 125D, the reflected laser beams L3 and L4 enter the polarization beam splitter (PBS) 126B.

Each of the PBSs 126A and 126B is formed by coupling two rectangular prisms, and has a cubic shape. In addition, a half-wave (phase-difference) element 127 is attached to a light-entrance face of the PBS 126B, and shifts the polarization directions of the laser beams L3 and L4 by 90 degrees.

In the case where the PBS 126A is arranged to reflect the P-wave components, when the laser beams L1 and L2 enter the PBS 126A, the S-wave components of the laser beams L1 and L2 pass through the PBS 126A and respectively enter the photodiodes 129A and 129B for detection of the optical output power, and the P-wave components of the laser beams L1 and L2 are reflected in the PBS 126A and enter the PBS 126B. The proportion of the P-wave component and the S-wave component can be changed by changing the polarization direction of the laser beams L1 and L2. In the above arrangement, a greater amount of light can be efficiently used by adjusting the polarization directions of the laser beams L1 and L2 so as to increase the proportion of the P-wave component.

In the case where the PBS 126B is arranged to reflect (or let through) the components opposite to the components reflected by the PBS 126A, i.e., the PBS 126B is arranged to reflect the S-wave components (opposite to the P-wave components reflected by the PBS 126A), the P-wave components of the laser beams L1 and L2 reflected by the PBS 126A can pass through the PBS 126B as they are. On the other hand, the half-wave element 127 shifts by 90 degrees the polarization directions of the laser beams L3 and L4 before the laser beams L3 and L4 enter the PBS 126B. This shift of the polarization directions increases the proportions of the S-wave components of the laser beams L3 and L4. That is, the S-wave components of the laser beams L3 and L4, which are reflected by the PBS 126B, increase. In addition, the decreased P-wave components of the laser beams L3 and L4 pass through the PBS 126B, and respectively enter the photodiodes 129C and 129D.

Thus, although the laser beams L1 and L2 and the laser beams L3 and L4 are substantially different polarization components, polarization beam combining (along the fast-axis direction) of the laser beams L1 and L3, polarization beam combining (along the fast-axis direction) of the laser beams L2 and L4, and angular beam combining (along the slow-axis direction) of the polarization-beam-combined laser beams L1 and L3 and the polarization-beam-combined laser beams L2 and L4 are realized in the PBS 126B in the combined laser-light sources 121.

Since each semiconductor laser (LD) has relatively low optical output power, the optical output power necessary for laser annealing by high-speed relative scanning cannot be achieved by use of only a single LD, and therefore the laser head 120 is constituted by the plurality of combined laser-light sources 121, each of which is constituted by the plurality of LD packages 123A to 123D. If the laser beams outputted from the plurality of LD packages 123A to 123D in each combined laser-light source 121 are combined by only the angular beam combining, the focal depth becomes small, and variations in the optical intensity caused by defocusing can occur.

The multimode transverse semiconductor lasers (LD) have a beam spread of 40 to 60 degrees in the fast-axis direction and a beam spread of 15 to 25 degrees in the slow-axis direction. In the laser annealing system according to the present embodiment, the variations in the optical intensity caused by defocusing are suppressed by performing, on of the laser beams L1 to L4, the polarization beam combining along the fast-axis direction and the angular beam combining along the slow-axis direction, so that the necessary optical output power is obtained.

The high-order transverse-mode laser light of each order emitted from each multiple-transverse-mode semiconductor laser diode (LD) contains two wavefront components propagating approximately symmetrical directions with respect to the optical axis. In order to reduce interference between the two wavefront components, each combined laser-light sources 121 further comprises a half-wave element 128, which is arranged at the light-exit port of the combined laser-light source 121, and shifts the polarization direction of one of the two wavefront components by 90 degrees. The interference between such two wavefront components and the function of the half-wave element 128 are explained below with reference to FIGS. 12A and 12B.

FIG. 12A shows a near-field pattern (NFP) and a far-field pattern (FFP) of laser light emitted from a semiconductor laser oscillating in a high-order transverse mode, and FIG. 12B shows an optical waveguide of the semiconductor laser.

The multiple-transverse-mode LD concurrently oscillates laser light in a plurality of different high-order transverse modes. As illustrated in FIG. 12A, the near-field image NFP(m) of the laser light in a high-order transverse mode of arbitrary order m has an optical intensity distribution having a plurality of peaks according to the order m, and the phases of adjacent ones of the peaks are opposite. As schematically illustrated in FIG. 12B, the optical waveguide R in the multiple-transverse-mode LD has two side edges E1 and E2 parallel to the optical axis A. Since the light in a high-order transverse mode of arbitrary order is repeatedly reflected between the two side edges E1 and E2 before the laser light in the mode is outputted, the laser light in the mode includes two wavefront components W1 and W2 which propagate in approximately symmetrical directions with respect to the optical axis A and are superposed on each other.

That is, when the wave component W1 is reflected by the side edge E1, the wave component W2 is reflected by the side edge E2 approximately concurrently with the reflection of the wave component W1. Then, when the wave component W1 is reflected by the side edge E2, the wave component W2 is reflected by the side edge E1 approximately concurrently with the reflection of the wave component W1. It is considered that the near-field image NFP(m) having the aforementioned distributions of the optical intensity and the phase is formed by interference between the wavefront components W1 and W2.

Since the multiple-transverse-mode LD concurrently oscillates laser light in the plurality of different high-order transverse modes in practice, the actual near-field image NFP is formed by superposition of a plurality of near-field images NFP (m) in the plurality of different high-order transverse modes.

In the laser light in each high-order transverse mode, two wavefront components W1 and W2 propagate in approximately symmetrical directions with respect to the optical axis A, and form a far-field image FFP(m) having a bimodal intensity distribution having peaks P1 and P2 and being approximately symmetrical with respect to the optical axis A. The peak-separation angle θ between the peaks P1 and P2 in each high-order transverse mode is determined on the basis of the order of the transverse mode, the stripe width and the refractive-index distribution of the optical waveguide R of the multiple-transverse-mode LD, the oscillation wavelength, and the like, and tends to increase with the order of the transverse mode. In FIG. 12A, the far-field image FFP(m) exhibiting the greatest peak-separation angle θ are illustrated with solid curves, and the far-field images FFP(m) in the other high-order transverse modes are illustrated with dashed curves.

Although interference between different high-order transverse modes is low, interference between the wavefront components W1 and W2 in each high-order transverse mode is high. Therefore, according to the present embodiment, the half-wave element 128, which shifts the polarization direction of one of the two wavefront components by 90 degrees, is provided in each combined laser-light sources 121 so as to reduce the interference between the two wavefront components W1 and W2 in each high-order transverse mode and uniformize the optical intensity distribution of the laser light outputted from the combined laser-light sources 121.

As explained above, in each combined laser-light sources 121, the collimator lenses 124A to 124D, the reflection mirrors 125A to 125D, the PBSs 126A and 126B, the half-wave element 127, and the half-wave element 128 constitute a combined optical system which optically combine the laser beams L1 to L4 emitted from the four LD packages 123A to 123D.

Referring back to FIG. 10, the laser annealing system 100 further comprises a prism array 132 (as a deflector), which is attached to the light-exit face of the laser head 120 constituted by the plurality of combined laser-light sources 121. The prism array 132 is constituted by a plurality of prisms 132a. The positions and the prism angles of the prisms 132a are set in correspondence with the positions of the respective combined laser-light sources 121.

The optical scanning system 140 is constituted by an optical scanning mirror (dynamic deflector) 141 (such as a galvano mirror) and a collimator lens 142. The laser light L outputted from the combined laser-light sources 121 is deflected by the prism array 132, and incident on the optical scanning mirror 141, so that the laser light L is relatively scanned in the x direction. The collimator lens 142 is moved in correspondence with the relative scanning of the laser light L, so that the laser light L deflected by the optical scanning mirror 141 is collimated by the collimator lens 142.

The laser annealing system 100 according to the present embodiment having the above construction outputs a laser beam having a cross section elongated in the y direction, and applies the laser beam to the semiconductor film 20. In the laser annealing system 100 constructed by the present inventors, the laser beam has an optical power density of 0.5 to 2.7 W/cm² a cross section with the dimensions of 20×4 micrometers to 40×8 micrometers at the surface of the semiconductor film 20.

In the laser annealing system 100 according to the present embodiment, the irradiation condition of the laser light L is set so that granular-crystal regions and noncrystalline regions at the surface of the semiconductor film 20 are melted by the irradiation, and lateral-crystal regions at the surface of the semiconductor film 20 are not melted by the irradiation.

Specifically, in the case where the semiconductor film 20 is a noncrystalline silicon film, it is preferable that the irradiation condition of the laser light L is set so that the absorptance A_{L} of the lateral-crystal regions, the absorptance A of the granular-crystal regions, and the absorptance A_{N} of the noncrystalline regions to the laser light satisfy the aforementioned conditions (1) and (2).
0.82≦(A_{G}/A_{N})≦1.0 (1)
(A_{L}/A_{N})≦0.70 (2)

In addition, in the case where the semiconductor film 20 is a noncrystalline silicon film, it is also preferable that the wavelength λ of the laser light L and the film thickness t satisfy the aforementioned condition (3).
0.8t+320 nm≦λ≦0.8t+400 nm (3)

In the case where the semiconductor film 20 is a noncrystalline silicon film, it is further preferable that the oscillation wavelengths of the semiconductor laser diodes (LDs) in the combined laser-light sources 121 in the laser head 120 be in the wavelength range of 350 to 500 nm. For example, GaN-based semiconductor lasers each having an active layer which contains one or more nitrogenous semiconductor compounds (such as GaN, AlGaN, InGaN, InAlGaN, InGaNAs, GaNAs, and the like) or group II-VI compound-based semiconductor lasers (such as ZnO-based or ZnSe-based semiconductor lasers) can be used.

In the case where the semiconductor film 20 laser annealed by the laser annealing system 100 is a noncrystalline silicon film, it is preferable that the relative scanning speed v (m/sec) of the laser light L and the absorption power density P (MW/cm²) in the noncrystalline regions satisfy the aforementioned condition (5).
0.44v^{0.34143}≦P≦0.56v^{0.34143} (5)

Furthermore, it is preferable that the laser annealing system 100 perform laser annealing so that the region irradiated with the laser light L during a relative scan in the x direction after a shift of the y position (after a change of an irradiated area) partially overlaps the region irradiated with the laser light L during the immediately preceding relative scan before the shift.

When the laser annealing system 100 according to the present embodiment is used, it is possible to perform the laser annealing process according to the present invention.

### EXAMPLES OF VARIATIONS

The construction and the manner of operations of the laser annealing system 100 are not limited to the construction and the manner explained above, and can be modified as appropriate within the scope of the present invention.

For example, in the explained embodiment, the irradiation of the semiconductor film 20 with the laser light L is realized by the movement (translation) of the stage 110 and the dynamic deflection of the light by the optical scanning system 140. Alternatively, the relative scanning in the x and y directions may be realized by movement (translation) of the laser head 120 in both of the x and y directions, movement (translation) of the stage 110 in both of the x and y directions, or dynamic deflection of the laser light L in both of the x and y directions, or the like.

In order to obtain a laser beam having an elongated cross section, it is preferable that a plurality of combined laser-light sources 121 be installed in the laser head 120, and each combined laser-light sources 121 be constituted by a plurality of multiple-transverse-mode LDs, as the laser annealing system 100 according to the present embodiment. The number of the multiple-transverse-mode LDs contained in each combined laser-light sources 121 may not be limited to four, and may be appropriately determined according to the design. Alternatively, the laser head 120 may include only a single combined laser-light source 121 or only a single multiple-transverse-mode LD.

Semiconductor Film, Semiconductor Device, and Active-Matrix Substrate

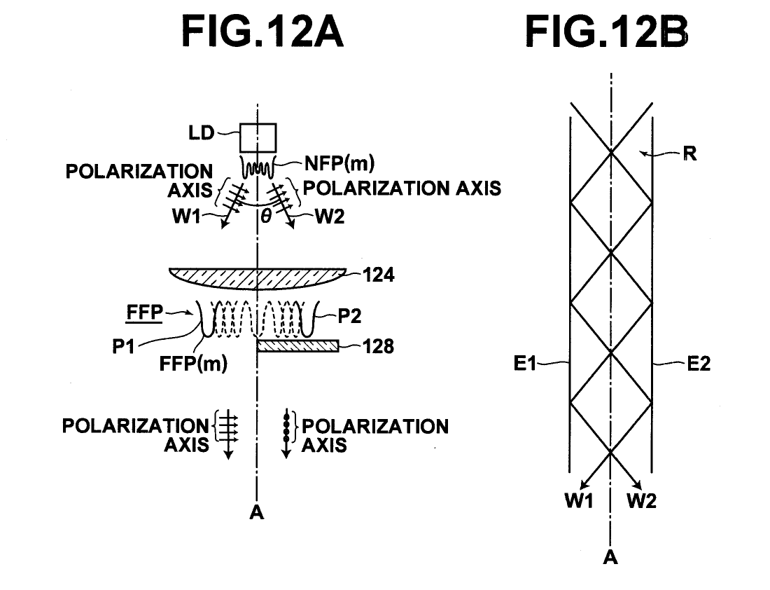

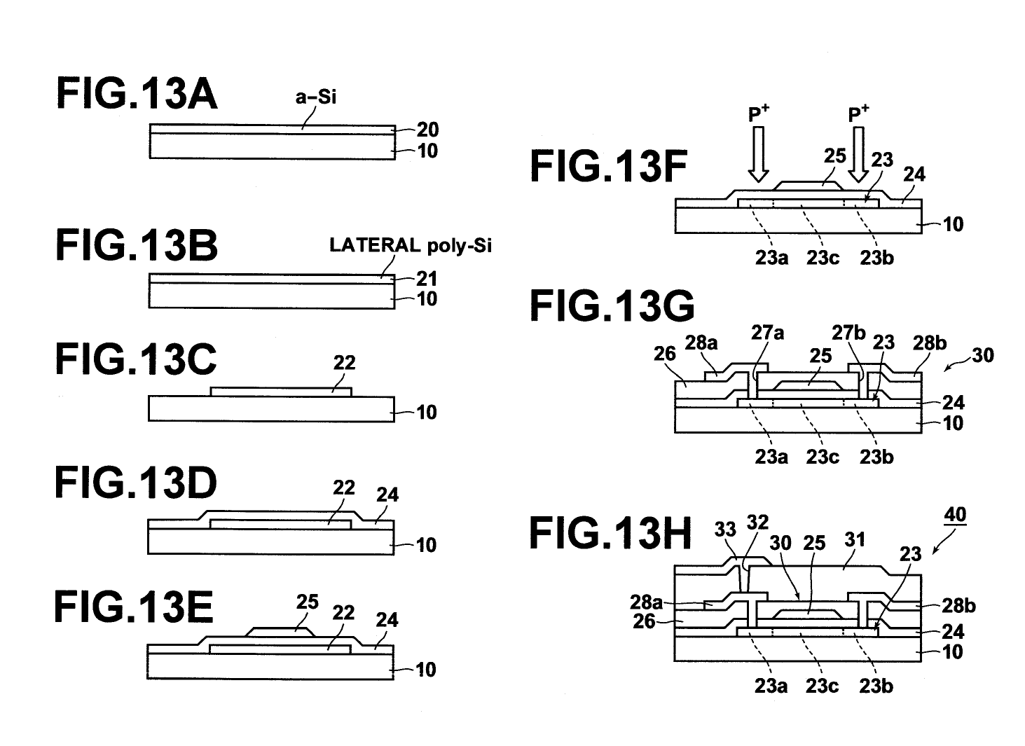

Hereinbelow, a process for producing a semiconductor film according to the present invention, a semiconductor device using the semiconductor film, and an active-matrix substrate having the semiconductor device, and the structures of the semiconductor film, the semiconductor device, and the active-matrix substrate are explained with reference to FIGS. 13A to 13H, which are cross-sectional views of the structures in representative stages in the process for producing the semiconductor film, the semiconductor device, and the active-matrix substrate. In the examples explained below, the semiconductor device is an top-gate thin-film transistor (TFT) for pixel switching, and the active-matrix substrate comprises switching elements each of which is realized by the above TFT.

In the first step in the process illustrated in FIG. 13A, a noncrystalline semiconductor film 20 is formed over the entire upper surface of a substrate 10. In the example illustrated in FIG. 13A, the noncrystalline semiconductor film 20 is an amorphous silicon (a—Si) film. There is no limitation on the substrate 10. For example, the substrate 10 is a glass substrate (such as a quartz glass substrate, a barium borate glass substrate, or an alminoborosilicate glass substrate), or a substrate produced by forming an insulation film on a surface of a heat-resistant adiathermanous substrate of plastic, silicon, or metal (e.g., stainless steel) and making the insulation film adiathermanous, where the heat resistance of the substrate of plastic, silicon, or metal is such as to resist heat treatment which is performed during the TFT formation process according to the present embodiment and the postprocessing after the TFT formation process, and the adiathermancy of the substrate of plastic, silicon, or metal is equivalent to or higher than the adiathermancy of glass.

Although the semiconductor film 20 may be directly formed on the surface of the substrate 10, alternatively, the semiconductor film 20 may be formed after a bedding layer (not shown) of silicon oxide, silicon nitride, or the like is formed on the surface of the substrate 10. The manner of forming the semiconductor film 20 and the bedding layer is not specifically limited, and may be a vapor phase technique such as plasma CVD (chemical vapor deposition), LPCVD (low-pressure CVD), or sputtering.

The thickness of the bedding layer is not specifically limited, and is preferably approximately 200 nm. The thickness of the semiconductor film 20 is not specifically limited, and is preferably approximately 40 to 120 nm, and is, for example, approximately 50 nm.

In the case where the semiconductor film 20 is formed by plasma CVD, the semiconductor film 20 contains a lot of hydrogen. When the semiconductor film 20 containing a lot of hydrogen is crystallized, bumping of the hydrogen occurs, so that the surface of the semiconductor film 20 can be roughened, and the semiconductor film 20 can partially come off. Therefore, it is preferable to dehydrogenate the semiconductor film 20 before the laser annealing. The manner of the dehydrogenation is not specifically limited, and the dehydrogenation may be realized by thermal annealing (which is performed, for example, at approximately 500° C. for approximately 10 minutes).

Next, in the second step in the process illustrated in FIG. 13B, the laser annealing according to the embodiment as explained before is performed on the entire semiconductor film 20 so as to crystallize the entire area of the semiconductor film 20. According to the present embodiment, approximately the entire area of the semiconductor film 20 is transformed into lateral crystals.

Thereafter, in the third step in the process illustrated in FIG. 13C, portions of the laser-annealed semiconductor film 21 other than the portions in which TFT elements are to be formed are removed by performing photolithography patterning on the laser-annealed semiconductor film 21. In FIG. 13C, the portions of the laser-annealed semiconductor film 21 remaining after the removal are indicated by the reference 22.

In the fourth step in the process illustrated in FIG. 13D, a gate insulation film 24 of SiO₂ or the like is formed by CVD, sputtering, or the like over the structure formed in the third step. The thickness of the gate insulation film 24 is not specifically limited. An example of a preferable thickness of the gate insulation film 24 is approximately 100 nm.

In the fifth step in the process illustrated in FIG. 13E, a gate electrode 25 is formed on the semiconductor film 22 by covering with an electrode material the upper side of the structure formed in the fourth step, and performing photolithography patterning.

In the sixth step in the process illustrated in FIG. 13F, portions of the semiconductor film 22 are doped with a dopant such as phosphorus (P), boron (B), or the like by using the gate electrode 25 as a mask, so that active regions are formed as a source region 23a and a drain region 23b. The region of the semiconductor film 22 between the source region 23a and the drain region 23b becomes a channel region 23c. In FIG. 13F, it is assumed that the dopant is phosphorus. An example of a preferable dopant dosage is approximately 3.0×10¹⁵ ions/cm². Thus, a silicon film 23 having the source region 23a, the channel region 23c, and the drain region 23b is obtained for use as an active layer of each TFT.

In the seventh step in the process illustrated in FIG. 13G, an interlayer insulation film 26 of SiO₂, SiN, or the like is formed over the upper side of the structure formed in the sixth step, and then contact holes 27a and 27b are formed through the interlayer insulation film 26 by etching (e.g., dry etching or wet etching) so that the contact holes 27a and 27b reach the source region 23a and the drain region 23b, respectively. Thereafter, a source electrode 28a and a drain electrode 28b are respectively formed on predetermined areas of the interlayer insulation film 26 over the contact holes 27a and 27b so that the contact holes 27a and 27b are respectively filled with the source electrode 28a and the drain electrode 28b, and the source electrode 28a and the drain electrode 28b respectively come into contact with the source region 23a and the drain region 23b.

Thus, the production of the TFT 30 according to the present embodiment is completed. In addition, the laser-annealed semiconductor film 21 (illustrated in FIG. 13B) before the patterning, the semiconductor film 22 (illustrated in FIG. 13B) after the patterning and before the doping, and the silicon film 23 (illustrated in FIG. 13F) after the doping each correspond to the semiconductor film (which is laser annealed by the laser annealing process) according to the present invention.

Next, in the eighth step in the process illustrated in FIG. 13H, an interlayer insulation film 31 of SiO₂, SiN, or the like is formed over the upper side of the structure formed in the seventh step, and then a contact hole 32 is formed through the interlayer insulation film 31 by etching (e.g., dry etching or wet etching) so that contact hole 32 reaches the source electrode 28a. Thereafter, a pixel electrode 33 is formed on a predetermined area of the interlayer insulation film 31 over the contact hole 32 so that the contact hole 32 is filled with the pixel electrode 33, and the pixel electrode 33 comes into contact with the source electrode 28a.

Although the structures in the respective steps in a process for producing a portion containing a TFT and a pixel electrode are illustrated in FIGS. 13A to 13H, in practice, a number of TFTs are formed on the substrate 10 so that the TFTs are arrayed in a matrix, and a great number of pixel electrodes are formed over the corresponding TFTs. Normally, a pixel electrode and a TFT for pixel switching are formed for each dot in the active-matrix substrates for the liquid-crystal display devices (LCDs), and a pixel electrode and two TFTs for pixel switching are formed for each dot in the active-matrix substrates for the electroluminescence (EL) display devices.

Thus, the production of the active-matrix substrate 40 according to the present embodiment is completed in the eighth step. Although not shown, in practice, wirings for relatively scanning lines and signal lines are also formed during the production of the active-matrix substrate 40. The relative scanning lines may be formed together with or separately from the gate electrodes 25, and the signal lines may be formed together with or separately from the drain electrodes 28b.

The laser-annealed semiconductor film 21, the semiconductor film 22, and the silicon film 23 produced during the above process are laser annealed by using the laser annealing process according to the present invention. Therefore, the laser-annealed semiconductor film 21, the semiconductor film 22, and the silicon film 23 have high crystallinity, and are suitable for use as the active layers of TFTs. In addition, since the TFTs 30 according to the present embodiment are produced by using the laser-annealed semiconductor film 21, the semiconductor film 22, and the silicon film 23, the TFTs 30 are superior in the element characteristics (such as the carrier mobility) and the element uniformity. Therefore, the active-matrix substrate 40 having the TFTs 30 formed as above exhibits high performance when the active-matrix substrate 40 is used in an electro-optic device.

In some electro-optic devices such as the liquid-crystal display devices (LCDs) and the electroluminescence (EL) display devices, a great number of pixel electrodes and a great number of TFTs for pixel switching are arranged in a matrix on a substrate, and driver circuits for driving the pixel electrodes and the TFTs are also arranged on the same substrate, where the driver circuits are formed of a plurality of driver TFTs. Normally, the driver circuits have CMOS structures constituted by N-type TFTs and P-type TFTs.

Since the semiconductor film 20 can be substantially entirely transformed into lateral crystals by using the laser annealing process according to the present invention, the present invention enables concurrent formation of the active layers of the TFTs for pixel switching and the active layers of the driver TFTs and manufacture of the driver TFTs having superior element characteristics such as the carrier mobility.

Electro-Optic Device

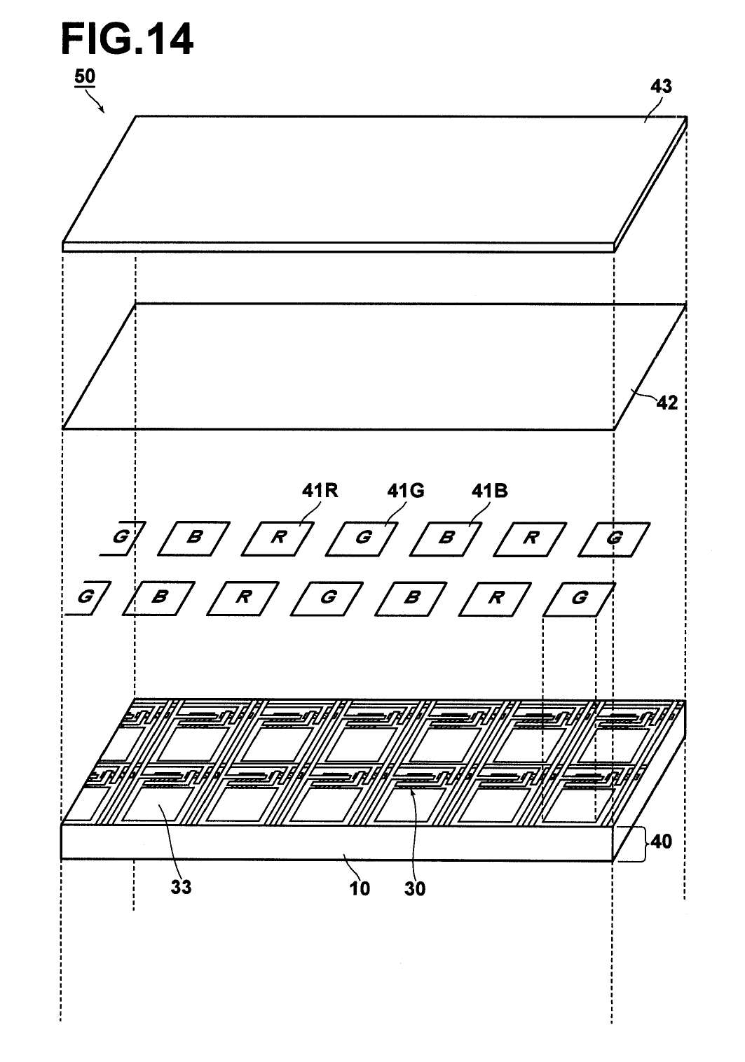

Hereinbelow, the structure of an electro-optic device according to the embodiment of the present invention is explained. The present invention can be applied to an organic electroluminescence (EL) device or a liquid crystal device. In the following explanations, the present invention is applied to an organic EL device as an example. FIG. 14 is an exploded perspective view of an organic EL device as an example of the electro-optic device according to the embodiment.

As illustrated in FIG. 14, the organic EL device 50 according to the present embodiment is produced by forming light emission layers 41R, 41G, and 41B in predetermined patterns on the active-matrix substrate 40, and thereafter forming a common electrode 42 and a sealing film 43 in this order over the light emission layers 41R, 41G, and 41B. The light emission layers 41R, 41G, and 41B respectively emit red light (R), green light (G), and blue light (B) when electric current is applied to the light emission layers 41R, 41G, and 41B. The light emission layers 41R, 41G, and 41B are formed in predetermined patterns corresponding to the pixel electrodes 33 so that each pixel is constituted by three dots respectively emitting red light, green light, and blue light. The common electrode 42 and the sealing film 43 are formed over the substantially entire upper surface of the active-matrix substrate 40. Alternatively, the organic EL device 50 may be sealed by using another type of sealing member such as a metal can or a glass substrate, instead of the sealing film 43. In this case, a drying agent such as calcium oxide may be contained in the sealed structure of the organic EL device 50.

In the organic EL device 50, the polarity of the pixel electrodes 33 is opposite to the polarity of the common electrode 42. That is, the pixel electrodes 33 are cathodes when the common electrode 42 is an anode, and the pixel electrodes 33 are anodes when the common electrode 42 is a cathode. The light emission layers 41R, 41G, and 41B emit light when positive holes injected from an anode and electrons injected from a cathode recombine and recombination energy is released.

Further, in order to increase the emission efficiency, it is possible to arrange a positive-hole injection layer and/or a positive-hole transportation layer between the anode(s) and the light emission layers 41R, 41G, and 41B, and/or arrange an electron injection layer and/or an electron transportation layer between the cathode(s) and the light emission layers 41R, 41G, and 41B.

Since the electro-optic device (the organic EL device) 50 according to the present embodiment is constructed by using the active-matrix substrate 40 as explained before, the TFTs 30 constituting the electro-optic device are superior in the element characteristics (such as the carrier mobility) and the element uniformity. Therefore, the electro-optic device according to the present embodiment is superior in the electro-optic characteristics such as the display quality.

### CONCRETE EXAMPLES OF THE PRESENT INVENTION

The present inventors have produced a concrete example 1 of the semiconductor film according to the present invention and comparison examples 1 and 2 as indicated below.

### Concrete Example 1

A concrete example 1 of the semiconductor film according to the present invention has been produced in accordance with the following procedure.

A bedding layer of silicon oxide having a thickness of 20 nm and a noncrystalline silicon (a—Si) film having a thickness of 50 nm are formed in this order on a glass substrate by plasma CVD. Thereafter, heat annealing is performed at approximately 500° C. for approximately 10 minutes, and dehydrogenation of the noncrystalline silicon film is performed.

Next, laser annealing of the noncrystalline silicon film is performed by using the laser annealing system 100 as illustrated in FIGS. 10 and 11, where GaN-based semiconductor lasers having the oscillation wavelength of 405 nm are used in the laser-light source, and the laser beam L has an elongated rectangular cross section with the dimensions of 20×3 micrometers at the surface of the noncrystalline silicon film. The noncrystalline silicon film has been substantially entirely laser annealed under each of the following conditions 1 to 4.

<Condition 1>

The condition 1 is that the speed of relative scanning with the laser light is 0.01 m/sec, the absorption power density in the noncrystalline regions is 0.1 MW/cm², and the overlapping ratio is 75%.

The overlapping ratio of 75% means that the y position is shifted by 5 micrometers after each relative scan in the x direction with the laser beam having the width of 20 micrometers is performed, so that the area with the width of 15 micrometers are overlappingly irradiated in the next relative scan.

FIGS. 15A and 15B respectively show SEM and TEM photographs of a surface of the silicon film which has been obtained as the concrete example 1 after the silicon film is substantially entirely laser annealed under the condition 1 according to the embodiment of the present invention. As indicated in FIGS. 15A and 15B, in the case where the semiconductor film is laser annealed under the condition 1, even when the lateral-crystal regions are irradiated with the laser light, lateral-crystal regions do not melt although granular-crystal regions and noncrystalline regions melt, so that a laterally-crystallized film having almost no granular crystal regions and no seam in substantially the entire area is obtained. In addition, it is possible to align the orientations of the lateral crystals so as to be within 5 degrees of the main scanning direction of the laser light.

Further, the present inventors have confirmed that a laterally-crystallized film having almost no granular crystal regions and no seam in substantially the entire area is also obtained in the case where the semiconductor film is laser annealed under each of the following conditions 2, 3, and 4.

<Condition 2>

The condition 2 is that the speed of relative scanning with the laser light is 1.0 m/sec, the absorption power density in the noncrystalline regions is 0.5 MW/cm², and the overlapping ratio is 75%.

<Condition 3>

The condition 3 is that the speed of relative scanning with the laser light is 0.1 m/sec, the absorption power density in the noncrystalline regions is 0.15 MW/cm², and the overlapping ratio is 75%.

<Condition 4>

The condition 4 is that the speed of relative scanning with the laser light is 0.01 m/sec, the absorption power density in the noncrystalline regions is 0.1 MW/cm², and the overlapping ratio is 25%.

When the speed of relative scanning with the laser light is smaller, heat spreads more easily, so that granular crystals are more likely to be produced. However, in the case where the laser annealing process according to the present embodiment is used, even when the laser annealing is performed with the relative scanning speed of 0.01 m/sec, the lateral crystals produced by each relative scan with the laser light are not melted by a subsequent relative scan with the laser light (performed in the overlapping manner) although granular-crystal regions and noncrystalline regions are melted by the subsequent relative scan. Therefore, the aforementioned laterally-crystallized films each having almost no granular crystal regions and no seam in substantially the entire area have been obtained.

### Comparison Example 1

A comparison example 1 of the semiconductor film has been produced in accordance with a procedure which is different from the procedure used in the production of the concrete example 1 only in that the noncrystalline silicon film is substantially entirely laser annealed under the following condition 5.

<Condition 5>

The condition 5 is that the speed of relative scanning with the laser light is 0.01 m/sec, the absorption power density in the noncrystalline regions is 0.09 MW/cm², and the overlapping ratio is 70%.

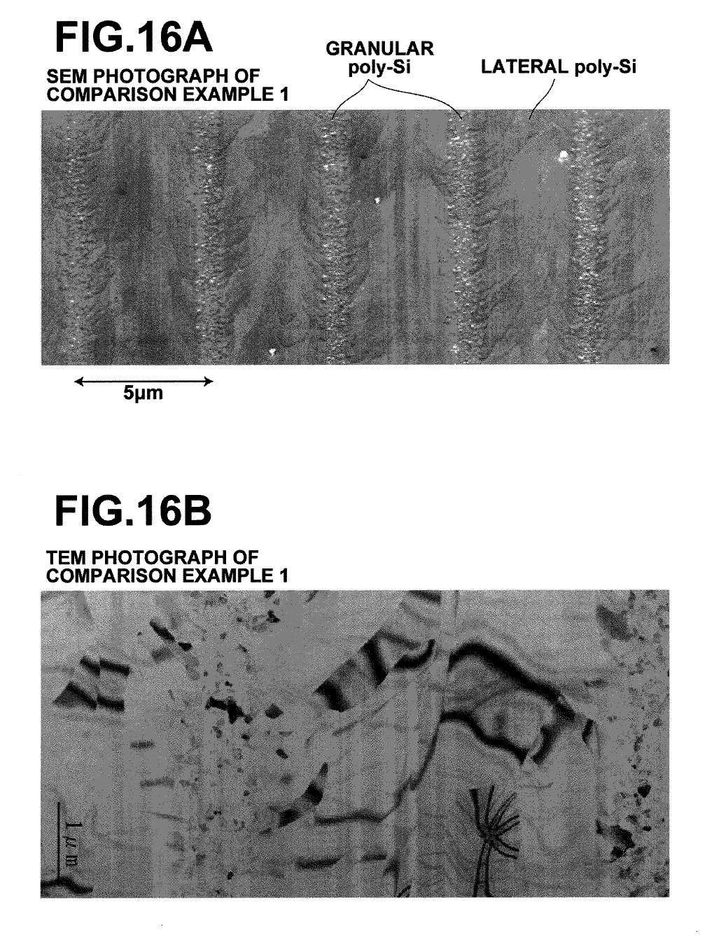

FIGS. 16A and 16B respectively show SEM and TEM photographs of a surface of the silicon film which has been obtained as the comparison example 1 after the silicon film is substantially entirely laser annealed under the condition 5. As indicated in FIGS. 16A and 16B, neither of the granular-crystal regions and the lateral-crystal regions melt even when the granular-crystal regions and the lateral-crystal regions are irradiated by a relative scan with laser light performed in the overlapping manner under the condition 5, so that the granular-crystal regions are not transformed into lateral crystals by the relative scan. In addition, since the granular crystals behave as nuclei, lateral crystals tend to grow in directions not parallel to the main scanning direction of the laser light (e.g., in directions different from the main scanning direction by 5 to 45 degrees), and the lateral crystals also tend to grow so as to align in the main scanning direction. Thus, production of curved lateral crystals has been observed. The observed proportion of the granular crystals in the entire film area is 30% or greater.

### Comparison Example 2

A comparison example 2 of the semiconductor film has been produced in accordance with a procedure which is different from the procedure used in the production of the concrete example 1 only in that the noncrystalline silicon film is substantially entirely laser annealed under the following condition 6.

<Condition 6>

The condition 6 is that the speed of relative scanning with the laser light is 0.01 m/sec, the absorption power density in the noncrystalline regions is 0.08 MW/cm², and the overlapping ratio is 70%. That is, the absorption power density in the noncrystalline regions in the condition 6 is lower than in the condition 5.

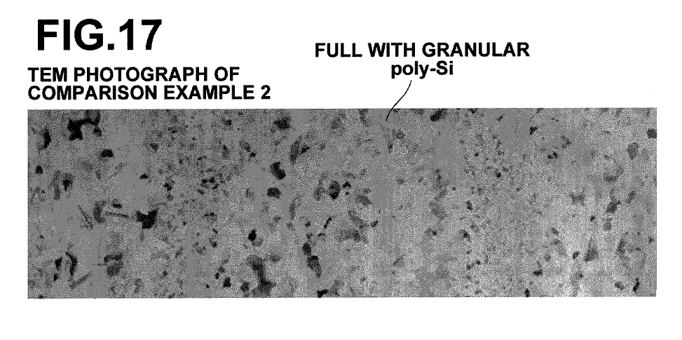

FIG. 17 is a TEM photograph of a surface of the silicon film as the comparison example 2 after the silicon film is substantially entirely laser annealed under the condition 6. As indicated in FIG. 17, even the noncrystalline regions are not transformed into lateral-crystal regions, so that granular crystals are produced in substantially the entire area of the silicon film obtained as the comparison example 2.

Vg-Id Characteristics

The present inventors have produced TFTs by using the silicon film obtained as the concrete example 1 by the laser annealing under the condition 1 and the silicon film obtained as the comparison example 1 by the laser annealing under the condition 5, and evaluated the Vg-Id characteristics of the TFTs. The Vg-Id characteristics are relationships between the gate voltage Vg and the drain current Id. In FIG. 18, “Comparison Example 1-A” and “Comparison Example 1-B” indicate two different samples of the TFTs produced by using the silicon film obtained as the comparison example 1. In addition, the Vg-Id characteristic of each of the TFT produced by using the silicon film as the concrete example 1 and the samples of the TFTs “Comparison Example 1-A” and “Comparison Example 1-B” is indicated on both of a linear scale (by a thin curve) and a logarithmic scale (by a thick curve). The coordinates of the linear scale and the logarithmic scale are indicated along the right and left sides of the graph, respectively. As indicated in FIG. 18, the TFT produced by using the silicon film as the concrete example 1 exhibits higher carrier mobility than and a superior element (current) characteristic to the TFTs produced by using the silicon film as the comparison example 1.

Other Matter

The laser annealing system and the laser annealing process according to the present invention can be preferably used in production of TFTs, production of electro-optic devices having TFTs, and the like.

What is claimed is:

1. A laser annealing process for performing laser annealing of a semiconductor film made of a noncrystalline semiconductor material, comprising the steps of:
(a) performing laser annealing of a first region of said semiconductor film by irradiating the first region with laser light under a condition for growing lateral crystals in the first region; and
(b) performing laser annealing of a second region of said semiconductor film by irradiating the second region with said laser light under such a condition that granular crystals and the noncrystalline semiconductor material in the second region are transformed into lateral crystals without melting lateral crystals produced in the semiconductor film by previous irradiation with the laser light, where the second region is shifted from a region of the semiconductor film which has been already irradiated with the laser light and includes at least a part of granular crystals which are produced by previous irradiation with the laser light and at least a part of the noncrystalline semiconductor material in said semiconductor film which has not yet been crystallized.

2. A laser annealing process according to claim 1, wherein said step (b) is repeated one or more times.

3. A laser annealing process according to claim 1, wherein said step (b) is executed so that the second region partially overlaps said region of the semiconductor film which has been already irradiated with the laser light.

4. A laser annealing process according to claim 1, wherein said semiconductor film is a silicon film, said granular crystals in the second region, said noncrystalline semiconductor material in the second region, and lateral crystals produced in the semiconductor film respectively have absorptances A_{G}, A_{N}, and A_{L}L, and said second region is irradiated in step (b) so that the absorptances A_{G}, A_{N}, and A_{L} satisfy the conditions,
0.82≦(A_{G}/A_{N})≦1.0, and
(A_{L}/A_{N})≦0.70.

5. A laser annealing process according to claim 4, wherein said laser light L has a wavelength λ, said semiconductor film has a thickness t, and the wavelength λ and the thickness t satisfy the condition,
0.8t+320 nm≦λ≦0.8t+400 nm.

6. A laser annealing process according to claim 5, wherein said thickness t satisfies the condition,
40 nm≦t≦120 nm.

7. A laser annealing process according to claim 1, wherein said laser light is continuous-wave laser light.

8. A laser annealing process according to claim 1, wherein said laser light is emitted from one or more semiconductor lasers.

9. A laser annealing process according to claim 1, wherein part of each of said first and second regions is concurrently irradiated with said laser light, and the first and second regions are irradiated with the laser light by relatively scanning the first and second regions with the laser light.

10. A laser annealing process according to claim 9, wherein said semiconductor film is a silicon film, said noncrystalline semiconductor material absorbs said laser light with an absorption power density P (MW/cm²), said second region is relatively scanned with the laser light at a relative scanning speed v (m/sec), and said relative scanning speed v (m/sec) and the absorption power density P (MW/cm²) satisfy the condition,
0.44v^{0.34143}≦P≦0.56v^{0.34143}.

11. A laser annealing system for performing laser annealing of a semiconductor film made of a noncrystalline semiconductor material, comprising a laser head in which one or more laser-light sources are installed, and which irradiates the semiconductor film with the laser light so as to performs the steps of,
(a) performing laser annealing of a first region of said semiconductor film by irradiating the first region with laser light under a condition for growing lateral crystals in the first region, and
(b) performing laser annealing of a second region of said semiconductor film by irradiating the second region with said laser light under such a condition that granular crystals and the noncrystalline semiconductor material in the second region are transformed into lateral crystals without melting lateral crystals produced in the semiconductor film by previous irradiation with the laser light, where the second region is shifted from a region of the semiconductor film which has been already irradiated with the laser light and includes at least a part of granular crystals which are produced by previous irradiation with the laser light and at least a part of the noncrystalline semiconductor material in said semiconductor film which has not yet been crystallized.

12. A laser annealing system according to claim 10, wherein said step (b) is repeated one or more times.

13. A laser annealing system according to claim 11, wherein said step (b) is executed so that the second region partially overlaps said region of the semiconductor film which has been already irradiated with the laser light.

14. A laser annealing system according to claim 11, wherein said semiconductor film is a silicon film, said granular crystals in the second region, said noncrystalline semiconductor material in the second region, and lateral crystals produced in the semiconductor film respectively have absorptances A_{G}, A_{N}, and A_{L}, and said second region is irradiated in step (b) so that the absorptances A_{G}, A_{N}, and A_{L} satisfy the conditions,
0.82≦(A_{G}/A_{N})≦1.0, and
(A_{L}/A_{N})≦0.70.

15. A laser annealing system according to claim 14, wherein said laser light L has a wavelength λ, said semiconductor film has a thickness t, and the wavelength λ and the thickness t satisfy the condition,
0.8t+320 nm≦λ≦0.8t+400 nm.

16. A laser annealing system according to claim 11, wherein said laser light is continuous-wave laser light.

17. A laser annealing system according to claim 11, wherein said laser light is emitted from one or more semiconductor lasers.

18. A laser annealing system according to claim 17, wherein said one or more semiconductor lasers has an oscillation wavelength in a range of 350 to 500 nm.

19. A laser annealing system according to claim 18, wherein said one or more semiconductor lasers are GaN-based semiconductor lasers or ZnO-based semiconductor lasers.

20. A laser annealing system according to claim 11, wherein said laser head concurrently irradiates part of each of said first and second regions with the laser light at each moment, and said laser annealing system further comprises a relative scanning unit which relatively scans each of the first and second regions with the laser light.

21. A laser annealing system according to claim 20, wherein said semiconductor film is a silicon film, said noncrystalline semiconductor material absorbs said laser light with an absorption power density P (MW/cm²), said second region is relatively scanned with the laser light at a relative scanning speed v (m/sec), and said relative scanning speed v (m/sec) and the absorption power density P (MW/cm²) satisfy the condition,
0.44v^{0.34143}≦P≦0.56v^{0.34143}.

22. A laser-annealed semiconductor film produced by performing the laser annealing process according to claim 1 on a noncrystalline semiconductor film.

23. A laser-annealed semiconductor film according to claim 22, wherein said semiconductor film is a noncrystalline silicon film.

24. A laser-annealed semiconductor film according to claim 22, which is formed of lateral crystals in a substantially entire area of the laser-annealed semiconductor film.

25. An unpatterned semiconductor film which is substantially entirely and seamlessly formed of lateral crystals on a substrate.

26. A semiconductor device comprising an active layer obtained by using the laser-annealed semiconductor film according to claim 22.

27. A semiconductor device comprising an active layer obtained by using the unpatterned semiconductor film according to claim 25.

28. An electro-optic device comprising the semiconductor device according to claim 26.

29. An electro-optic device comprising the semiconductor device according to claim 27.
